(19) United States
(12) Patent Application Publication
(10) Pub. No.: US 2026/0162738 A1
(43) Pub. Date: Jun. 11, 2026

(54) STORAGE DEVICE AND A METHOD OF OPERATING A STORAGE CONTROLLER

(71) Applicant: SAMSUNG ELECTRONICS CO., LTD., Suwon-si (KR)

(72) Inventors: Minji CHO, Suwon-si (KR); Jinyoung KIM, Suwon-si (KR); Eunhyang PARK, Suwon-si (KR)

(73) Assignee: SAMSUNG ELECTRONICS CO., LTD., Suwon-si (KR)

(21) Appl. No.: 19/387,040

(22) Filed: Nov. 12, 2025

(30) Foreign Application Priority Data
Dec. 10, 2024 (KR) 10-2024-0182199

(51) Int. Cl. G11C 16/34; G06F 11/10; G11C 16/04; G11C 16/08; G11C 16/10; G11C 16/26; G11C 16/30

(52) U.S. Cl. CPC G11C 16/3436; G06F 11/1044; G11C 16/0483; G11C 16/08; G11C 16/10; G11C 16/26; G11C 16/30

(57) ABSTRACT

A storage device include a nonvolatile memory device and a storage controller. The nonvolatile memory device includes at least one memory block including a plurality of cell strings. The at least one memory block is divided into a plurality of sub-blocks disposed in one direction. The storage controller includes a reclaim register, identifies the plurality of sub-blocks as a selected sub-block including a selected word-line and at least one unselected sub-block adjacent to the selected sub-block, based on an access address, adaptively determines K target word-lines of the selected sub-block and the at least one unselected sub-block based on a program progress state of each of the selected sub-block and the at least one unselected sub-block, and performs a reliability verification operation on the K target word-lines sequentially.

### CROSS-REFERENCE TO RELATED APPLICATION

This US application claims priority under 35 USC § 119 to Korean Patent Application No. 10-2024-0182199, filed on Dec. 10, 2024, in the Korean Intellectual Property Office (KIPO), the disclosure of which is incorporated herein by reference in its entirety.

### BACKGROUND

### 1. Technical Field

Example embodiments generally relate to semiconductor memory devices, and more particularly to a storage device and a method of operating a storage controller.

### 2. Discussion of the Related Art

Semiconductor memory devices for storing data may be classified into volatile memory devices and nonvolatile memory devices. Volatile memory devices, such as dynamic random access memory (DRAM) devices, are typically configured to store data by charging or discharging capacitors in memory cells, and lose the stored data when power is off. Nonvolatile memory devices, such as flash memory devices, may maintain stored data even though power is off. Volatile memory devices are widely used as main memories of various apparatuses, while nonvolatile memory devices are widely used for storing program codes and/or data in various electronic devices, such as computers, mobile devices, etc.

Flash memory device is being widely used as a high-capacity storage medium. Due to a physical characteristic of the flash memory device and/or various ambient factors, an error may occur in data that are stored in the flash memory device. The data error may be corrected through a separate error correction scheme. However, when an error occurs that exceeds an error correction limitation of the separate error correction scheme, such data may be lost. In this case, the reliability of the data stored in the flash memory device may be affected.

### SUMMARY

Some example embodiments may provide a storage device with enhanced reliability and enhanced performance.

Some example embodiments may provide a method of operating a storage controller configured to control a nonvolatile memory device with enhanced reliability and enhanced performance.

According to example embodiments, a storage device include a nonvolatile memory device and a storage controller. The nonvolatile memory device includes at least one memory block including a plurality of cell strings where each of the plurality of cell strings includes a string selection transistor, a plurality of memory cells and a ground selection transistor which are connected in series and disposed in a one direction between a bit-line and a common source line. The at least one memory block is divided into a plurality of sub-blocks disposed in the one direction. The storage controller includes a reclaim register, identifies, among the plurality of sub-blocks, a selected sub-block including a selected word-line and at least one unselected sub-block adjacent to the selected sub-block, based on an access address, adaptively determines K target word-lines of the selected sub-block and the at least one unselected sub-block based on a program progress state of each of the selected sub-block and the at least one unselected sub-block, and performs a reliability verification operation on the K target word-lines sequentially.

According to example embodiments, there is provided a method operating a storage controller to control a nonvolatile memory device. The nonvolatile memory device includes at least one memory block including a plurality of cell strings where each of the plurality of cell strings includes a string selection transistor, a plurality of memory cells and a ground selection transistor which are connected in series and disposed in one direction between a bit-line and a common source line and the at least one memory block is divided into a plurality of sub-blocks disposed in the one direction. According to the method, the plurality of sub-blocks is identified as a selected sub-block including a selected word-line and at least one unselected sub-block adjacent to the selected sub-block, based on an access address, K target word-lines of the selected sub-block and the at least one unselected sub-block is adaptively determined based on a program progress state of each of the selected sub-block and the at least one unselected sub-block, and a reliability verification operation is sequentially performed on the K target word-lines.

According to example embodiments, a storage device include a nonvolatile memory device and a storage controller. The nonvolatile memory device includes at least one memory block including a plurality of memory cells. The at least one memory block includes a plurality of sub-blocks. The storage controller identifies the plurality of sub-blocks as a selected sub-block including a selected word-line and at least one unselected sub-block adjacent to the selected sub-block, based on an access address, adaptively determines K target word-lines of the selected sub-block and the at least one unselected sub-block based on a program progress state of each of the selected sub-block and the at least one unselected sub-block, K being an integer greater than two and performs a reliability verification operation on the K target word-lines sequentially. The storage controller includes a reclaim register, a reliability manager, an error correction code (ECC) and a processor. The reliability manager performs the reliability verification operation based on read disturbance level monitoring scheme. The ECC engine detects and corrects an error of a read data read by the reliability manager by performing an ECC decoding on the read data. The processor controls the reliability manager and the ECC engine. Based on an error count in the read data being greater than a reference error count, the processor registers a corresponding sub-block in the reclaim register as a reclaimed sub-block.

Accordingly, the storage device and the method of operating a storage controller according to example embodiments, may designate at least one word-line sensitive to read disturbance as additional target word-lines, among word-lines of the unselected sub-block in addition to target word-lines sensitive to read disturbance, among word-lines of the selected sub-block, may perform the reliability verification operation on the target word-lines and the additional target word-lines and may perform reclaim operation based on a result of the reliability verification operation. Therefore, reliability and performance of the storage device may be enhanced.

### BRIEF DESCRIPTION OF THE DRAWINGS

Illustrative, non-limiting example embodiments will be more clearly understood from the following detailed description in conjunction with the accompanying drawings.

FIG. 1 is a flow chart illustrating a method of operating a storage controller to control a nonvolatile memory device according to example embodiments.

FIGS. 2A and 2B are flow charts illustrating an operation of adaptively determine K target word-lines in FIG. 1 according to example embodiments.

FIG. 3 is a flow chart illustrating an example of performing the reliability verification operation sequentially in FIG. 1 according to example embodiments.

FIG. 4 illustrates that one memory block is divided into sub-blocks and target word-lines of the sub-blocks.

FIGS. 5A and 5B illustrate examples of operation of FIG. 3, respectively, according to example embodiments.

FIG. 6 illustrates examples of an open sub-block, a closed sub-block and an erased sub-block according to example embodiments.

FIG. 7 is a graph showing a memory cell distribution change obtained through repetitive read operations.

FIG. 8 is a block diagram illustrating a storage device according to example embodiments.

FIG. 9 is a block diagram illustrating an example of the storage controller in the storage device of FIG. 8 according to example embodiments.

FIG. 10 is a block diagram illustrating an example of the nonvolatile memory device in the storage device of FIG. 8 according to example embodiments.

FIG. 11 schematically illustrates a structure of the nonvolatile memory device of FIG. 10 according to example embodiments.

FIG. 12 is a block diagram illustrating an example of the memory cell array in the nonvolatile memory device of FIG. 10 according to example embodiments.

FIG. 13 is a circuit diagram illustrating one of the memory blocks of FIG. 12 according to example embodiments.

FIG. 14 illustrates an example of a structure of a cell string in the memory block of FIG. 13.

FIG. 15 is a block diagram illustrating the control circuit in the nonvolatile memory device of FIG. 10 according to example embodiments.

FIG. 16 is a block diagram illustrating an example of the voltage generator in the nonvolatile memory device of FIG. 10 according to example embodiments.

FIG. 17 is a schematic diagram of a connection of the memory cell array and the page buffer circuit in FIG. 10, according to example embodiments.

FIGS. 18A, 18B and 18C illustrate a position of a boundary word-line based on program progress states of a selected sub-block and an unselected sub-block, respectively, according to example embodiments.

FIG. 19 illustrates a position of a boundary word-line based on program progress states of a selected sub-block and an unselected sub-block according to example embodiments.

FIG. 20 illustrates a position of a boundary word-line based on program progress states of a selected sub-block and an unselected sub-block according to example embodiments.

FIG. 21 is a diagram for describing an operating characteristic and a reliability verification operation of a memory block of FIG. 13.

FIG. 22 illustrates a connection example of a storage controller and a nonvolatile memory device in the storage device of FIG. 8 according to example embodiments.

FIG. 23 is a block diagram illustrating a storage device according to example embodiments.

### DETAILED DESCRIPTION OF THE EMBODIMENTS

Various example embodiments will be described more fully hereinafter with reference to the accompanying drawings, in which some example embodiments are shown.

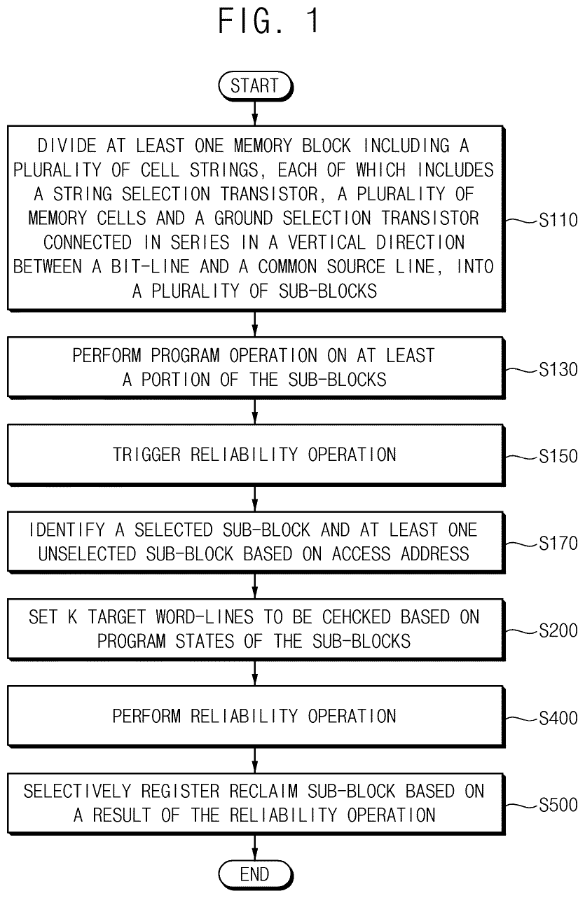

FIG. 1 is a flow chart illustrating a method of operating a storage controller to control a nonvolatile memory device according to example embodiments.

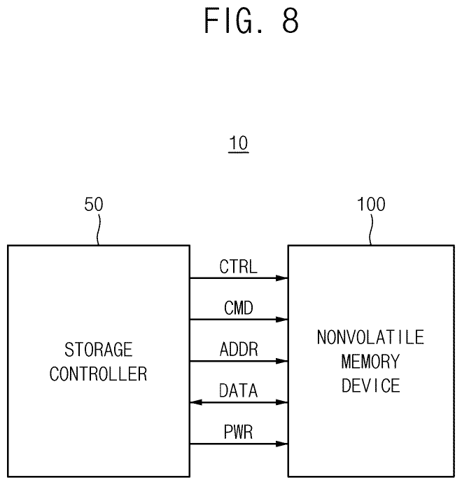

FIG. 1 illustrates a method of operating a storage controller (refer to 50 in FIG. 8) to control a nonvolatile memory device (refer to 100 in FIG. 8) including at least one memory block which includes a plurality of cell strings, where each cell string includes a string selection transistor, a plurality of memory cells and a ground selection transistor connected in series in a vertical direction between a bit-line and a common source line. According to example embodiments, the nonvolatile memory device may include a three-dimensional NAND flash memory device or a vertical NAND flash memory device. The common source line may be in a substrate and the vertical direction may be perpendicular to the substrate. The vertical direction may be referred to as one direction.

Referring to FIG. 1, the storage controller 50 divides the plurality of cell strings divided into a plurality of sub-blocks disposed in the vertical direction (operation S110). Each of the plurality of sub-blocks is smaller than a physical block of the nonvolatile memory device.

The storage controller 50 performs a program operation on at least a portion of the plurality of sub-blocks (operation S130).

The storage controller 50 may trigger a reliability verification operation (operation S150). The reliability verification operation may be referred to as a reliability operation and may be performed based on a read disturbance level monitoring scheme.

In example embodiments, the storage controller 50 may perform a read operation on at least one of target word-lines by using the read disturbance level monitoring scheme and may perform a reclaim operation when an error count in the read data is greater than a reference error count. In example embodiments, the read disturbance level monitoring scheme may be performed based on an on-chip valley search (OVS) algorithm. For example, the storage controller 50 may determine an optimal read voltage level based on the OVS algorithm, a shifted amount of the optimal read voltage level with respect to an initial read voltage level in bi-direction and may determine a reclaim based on the shifted amount.

For example, when a read count associated with a specific memory block reaches a predetermine period, the storage controller 50 may trigger the reliability verification operation on the specific memory block. For example, when a read count associated with a specific memory block reaches a reference read count, the storage controller 50 may trigger the reliability verification operation on the specific memory block.

The storage controller 50 may identify the plurality of sub-blocks as a selected sub-block including a selected word-line and at least one unselected sub-block based on access address (operation S170).

The storage controller 50 may adaptively determine K target word-lines of the selected sub-block and the at least one unselected sub-block based on a program progress state of each of the selected sub-block and the at least one unselected sub-block (operation S200). The reliability verification operation is to be performed on the K target word-lines. Here, K may be an integer greater than two.

In example embodiments, the program progress state of each of the selected sub-block and the at least one unselected sub-block includes an open state, a closed state and an erased state, the open state may indicate that each of the selected sub-block and the at least one unselected sub-block includes at least one erased word-line, the closed state may indicate that each of the selected sub-block and the at least one unselected sub-block includes only programmed word-lines and the erased state may indicate that each of the selected sub-block and the at least one unselected sub-block includes only erased word-lines. The selected word-line may be designated by the access address.

The storage controller 50 may perform the reliability verification operation on the K target word-lines sequentially (operation S400). In example embodiments, the reliability verification operation may indicate an operation of reading data from memory cells connected with at least one word-line among the K target word-lines, and detecting and correcting an error of the read data.

When an error count detected in memory cells coupled to a first target word-line of the selected sub-block during the reliability verification operation on the K target word-lines is greater than a reference error count, the storage controller 50 may skip the reliability verification operation on a second target word-line of the selected sub-block and may perform the reliability verification operation on at least one target word-line of the unselected sub-block.

The storage controller 50 may selectively register a sub-block including a word-line whose error count is greater than a reference error count in a reclaim register as a reclaimed sub-block based on a result of the reliability verification operation (operation S500). In example embodiment, the storage controller 50 may perform a reclaim operation on the reclaimed sub-block instead of registering the reclaimed sub-block in the reclaim register.

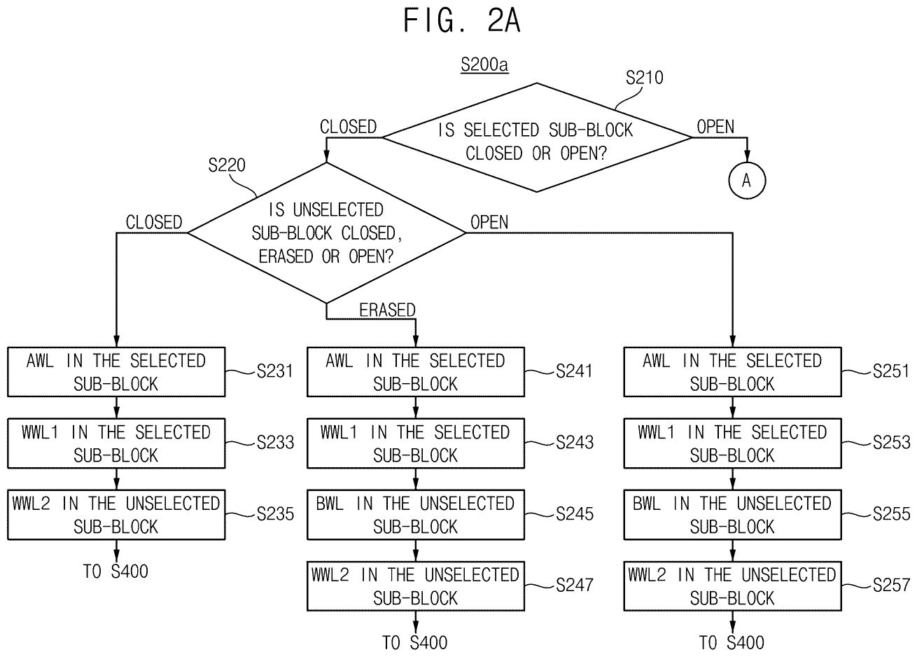

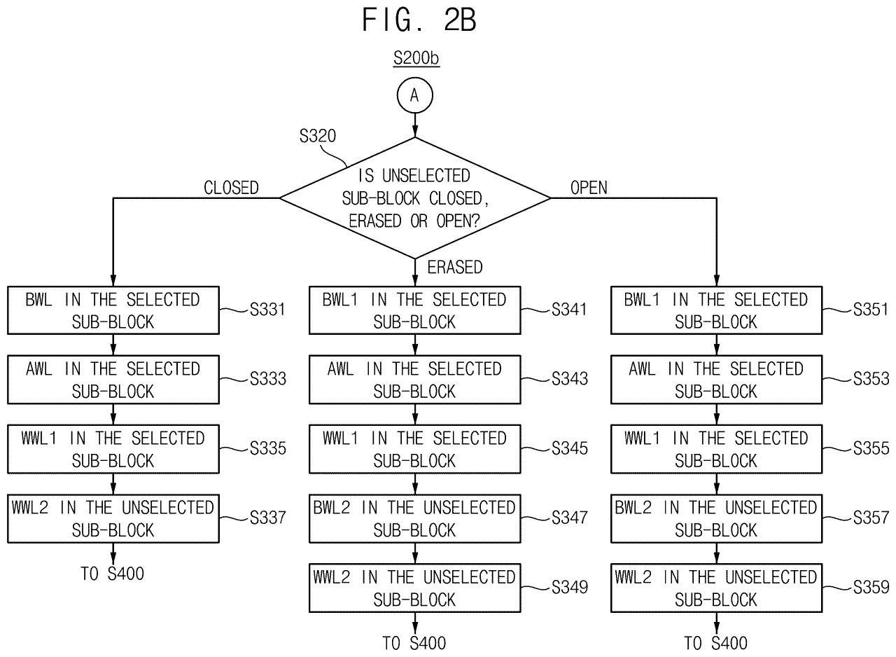

FIGS. 2A and 2B are flow charts illustrating an operation of adaptively determine the K target word-lines in FIG. 1 according to example embodiments.

Operation S200a of FIG. 2A and operation S200b of FIG. 2B may correspond to the operation S200 in FIG. 2.

In FIGS. 2A and 2B, assuming that one physical block is divided into two sub-blocks, however, operation S200a of FIG. 2A and operation S200b of FIG. 2B may be applied to a case in which one physical block is divided into three or more sub-blocks.

Referring to FIGS. 2A and 2B, for adaptively determine the K target word-lines (operations S200a and S200b), the storage controller 50 determines whether the selected sub-block is in the closed state or the open state (operation S210).

When the selected sub-block is in the closed state (CLOSED in S210), the storage controller 50 determines whether the unselected sub-block is in the closed state or the open state (operation S220).

When the unselected sub-block is in the closed state (CLOSED in S220), the storage controller 50 may determine (i) an adjacent word-line AWL adjacent to the selected word-line among first word-lines of the selected sub-block (operation S231), (ii) a first weak word-line WWL1 adjacent to the unselected sub-block among the first word-lines (operation S233) and (iii) a second weak word-line WWL2 adjacent to the selected sub-block among second word-lines of the unselected sub-block (operation S235) as the K target word-lines.

When the unselected sub-block is in the erased state (ERASED in S220), the storage controller 50 may determine (i) an adjacent word-line AWL adjacent to the selected word-line among first word-lines of the selected sub-block (operation S241), (ii) a first weak word-line WWL1 adjacent to the unselected sub-block among the first word-lines (operation S243), (iii) a boundary word-line BWL adjacent to at least one programmed word-line among second word-lines of the unselected sub-block (operation S245) and (iv) a second weak word-line WWL2 adjacent to the selected sub-block among the second word-lines (operation S247) as the K target word-lines.

When the unselected sub-block is in the open state (ERASED in S220), the storage controller 50 may determine (i) an adjacent word-line AWL adjacent to the selected word-line among first word-lines of the selected sub-block (operation S251), (ii) a first weak word-line WWL1 adjacent to the unselected sub-block among the first word-lines (operation S253), (iii) a boundary word-line BWL adjacent to at least one programmed word-line among second word-lines of the unselected sub-block (operation S255) and (iv) a second weak word-line WWL2 adjacent to the selected sub-block among the second word-lines (operation S257) as the K target word-lines.

When the selected sub-block is in the open state (OPENED in S210), the storage controller 50 determines whether the unselected sub-block is in the closed state or the open state (operation S320).

When the unselected sub-block is in the closed state (CLOSED in S320), the storage controller 50 may determine (i) a boundary word-line BWL adjacent to at least one programmed word-line among first word-lines of the selected sub-block (operation S331), (ii) an adjacent word-line AWL adjacent to the selected word-line among first word-lines of the selected sub-block (operation S333), (iii) a first weak word-line WWL1 adjacent to the unselected sub-block among the first word-lines (operation S335) and (iv) a second weak word-line WWL2 adjacent to the selected sub-block among second word-lines of the unselected sub-block (operation S337) as the K target word-lines.

When the unselected sub-block is in the erased state (ERASED in S320), the storage controller 50 may determine (i) a first boundary word-line BWL1 adjacent to at least one first programmed word-line among first word-lines of the selected sub-block (operation S341), (ii) an adjacent word-line AWL adjacent to the selected word-line among first word-lines of the selected sub-block (operation S343), (iii) a first weak word-line WWL1 adjacent to the unselected sub-block among the first word-lines (operation S345), (iv) a second boundary word-line BWL2 adjacent to at least one second programmed word-line among second word-lines of the unselected sub-block (operation S347) and (v) a second weak word-line WWL2 adjacent to the selected sub-block among the second word-lines (operation S349) as the K target word-lines.

When the unselected sub-block is in the open state (OPEN in S320), the storage controller 50 may determine (i) a first boundary word-line BWL1 adjacent to at least one first programmed word-line among first word-lines of the selected sub-block (operation S351), (ii) an adjacent word-line AWL adjacent to the selected word-line among first word-lines of the selected sub-block (operation S353), (iii) a first weak word-line WWL1 adjacent to the unselected sub-block among the first word-lines (operation S355), (iv) a second boundary word-line BWL2 adjacent to at least one second programmed word-line among second word-lines of the unselected sub-block (operation S357) and (v) a second weak word-line WWL2 adjacent to the selected sub-block among the second word-lines (operation S359) as the K target word-lines.

In FIGS. 2A and 2B, when the read operation performed, the pass voltage is applied to the adjacent word-line AWL, the adjacent word-line AWL may be greatly influenced by the read disturbance and the adjacent word-line AWL may be a target of the reliability verification operation. Position of the adjacent word-line AWL may vary based on a voltage level applied to the word-lines in the read operation. For example, when a voltage level of the read pass voltage applied to the unselected word-lines is greater than a voltage level of the read voltage applied to the selected word-line, one or more word-lines adjacent to the selected word-line may correspond to the adjacent word-line and the reliability verification operation may be performed on the adjacent word-line. For example, when a voltage level of the read pass voltage applied to the unselected word-lines is equal to or smaller than a voltage level of the read voltage applied to the selected word-line, one or more word-lines adjacent to the selected word-line may be excluded from target word-lines of the reliability verification operation.

In FIGS. 2A and 2B, the weak word-line AWL may be target of the reliability verification operation, because the weak word-line AWL may be greatly influenced by the read disturbance due to difference of hole pitch of a physical configuration of a sub-block. In example embodiments, the weak word-line may include a plurality of weak word-lines depending on manufacturing process of the nonvolatile memory device. The reliability verification operation may be performed on all of the plurality of weak word-lines or may be performed on one weak word-line selected randomly among the plurality of weak word-lines. The weak word-line(s) may be referred to as a sub-target word-line.

In FIGS. 2A and 2B, the boundary word-line BWL may be target of the reliability verification operation, because the boundary word-line BWL may be greatly influenced by the read disturbance due to physical adjacency to a programmed word-line.

In addition, when one physical block is divided into three or more sub-blocks, the storage controller 50 may adaptively determine target word-lines based on program progress states of a selected sub-block and one or more unselected sub-blocks, and may sequentially perform a reliability verification operation on at least one target word-line of the selected sub-block and at least one target word-line of each of the one or more unselected sub-blocks. In this case, a number of target word-lines may vary based on combination of a program progress state of the selected sub-block, a program progress state of a first unselected sub-block and a program progress state of a second unselected sub-block.

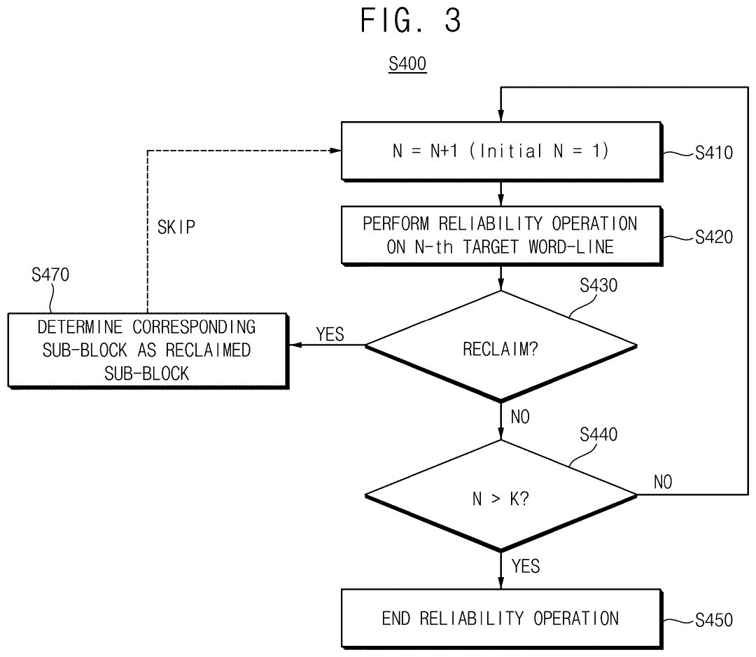

FIG. 3 is a flow chart illustrating an example of performing the reliability verification operation sequentially in FIG. 1 according to example embodiments.

Referring to FIG. 3, for performing the reliability verification operation sequentially (operation S400), the storage controller 50 may select an N-th target word-line among the K target word-lines (operation S410). Here, N may be one. The storage controller 50 may perform the reliability verification operation on the N-th target word-line (operation S420) and determine whether to reclaim the N-th target word-line based on error count obtained through the reliability verification operation (operation S430).

When the N-th target word-line is determined not to be reclaimed (NO in S430), the storage controller 50 determines whether N is greater than K (operation S440). When N is smaller than K (NO in S440), the storage controller 50 increases N by one (N=N+1) and repeats the operations S420, S430 and S440.

When the N-th target word-line is determined to be reclaimed (YES in S430), the storage controller 50 may register a selected sub-block including the N-th target word-line, may skip the reliability verification operation on (N+1)-th target word-line when the (N+1)-th target word-line is included in the selected sub-block including the N-th target word-line and may perform the reliability verification operation on (N+2)-th target word-line of an unselected sub-block.

When N is greater than K (YES in S440), the storage controller 50 may end the reliability verification operation (S450).

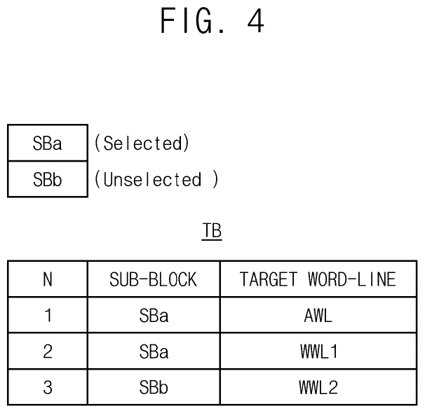

FIG. 4 illustrates that one memory block id divided into sub-blocks and target word-lines of the sub-blocks.

Referring to FIG. 4, one physical memory block may be divided into a first sub-block SBa and a second sub-block SBb, the first sub-block SBa may be a selected sub-block, and the second sub-block SBb may be an unselected sub-block. The first sub-block SBa may be stacked on the second sub-block SBb in a substrate.

A table TB in FIG. 4 illustrates target word-lines on which the reliability verification operation to be performed in the first sub-block SBa and the second sub-block SBb. A first target word-line (N=1) may be an adjacent word-line AWL adjacent to the selected word-line in the first sub-block SBa, a second target word-line (N=2) may be a first weak word-line WWL1 physically adjacent to the second sub-block SBb among first word-lines of the first sub-block SBa and third target word-line (N=3) may be a second weak word-line WWL2 physically adjacent to the first sub-block SBa among second word-lines of the second sub-block SBb.

A number of target word-lines, on which the reliability verification operation to be performed, in the first sub-block SBa and the second sub-block SBb may vary based a program progress state of each of the first sub-block SBa and the second sub-block SBb.

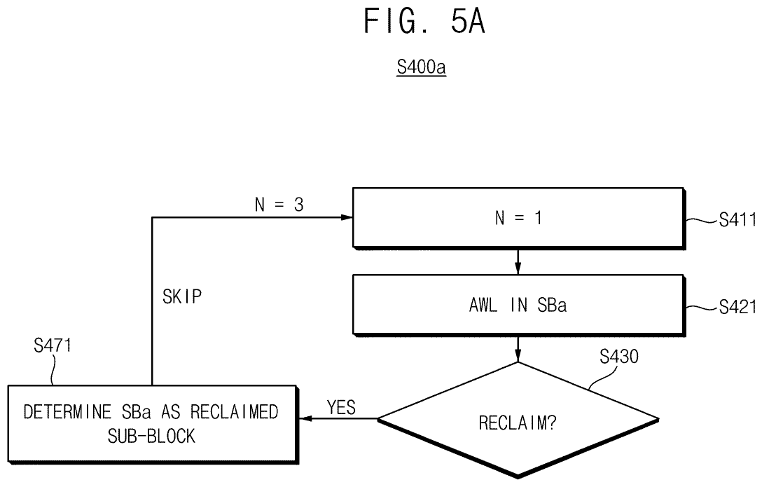

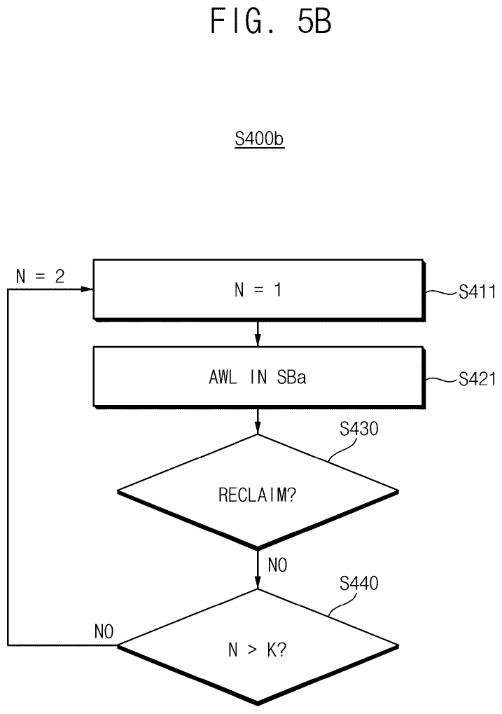

FIGS. 5A and 5B illustrate examples of operation of FIG. 3, respectively, according to example embodiments.

Referring to FIGS. 4 and 5A, the storage controller 50 may set the adjacent word-line AWL adjacent to the selected word-line in the first sub-block SBa as a first target word-line (N=1) (operation S411), may perform a reliability verification operation on the adjacent word-line AWL in the first sub-block SBa (operation S421), may determine whether to reclaim the adjacent word-line AWL in the first sub-block SBa based on a result of the reliability verification operation (operation S430), determine to reclaim the first sub-block SBa (operation S471) when the adjacent word-line AWL in the first sub-block SBa is determined to be reclaimed (YES in S430), may skip the reliability verification operation on the first weak word-line WWL1 physically adjacent to the second sub-block SBb among first word-lines of the first sub-block SBa and may set the second weak word-line WWL2 physically adjacent to the first sub-block SBa among second word-lines of the second sub-block SBb as a next target word-line (N=3).

Referring to FIGS. 4 and 5B, the storage controller 50 may set the adjacent word-line AWL adjacent to the selected word-line in the first sub-block SBa as a first target word-line (N=1) (operation S411), may perform a reliability verification operation on the adjacent word-line AWL in the first sub-block SBa (operation S421), may determine whether to reclaim the adjacent word-line AWL in the first sub-block SBa based on a result of the reliability verification operation (operation S430), when the adjacent word-line AWL in the first sub-block SBa is determined not to be reclaimed (NO in S430), may determine whether N is greater than K (operation S451), and may set the first weak word-line WWL1 physically adjacent to the second sub-block SBb among first word-lines of the first sub-block SBa as a next target word-line (N=2) when N is equal to or smaller than K (NO in S451).

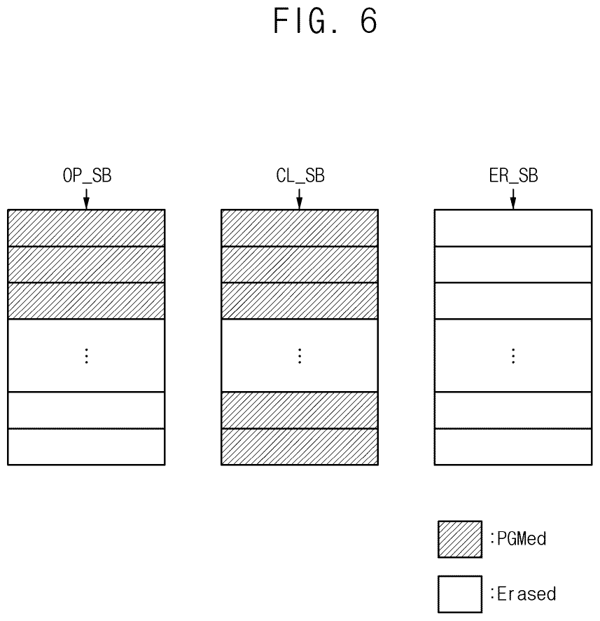

FIG. 6 illustrates examples of an open sub-block, a closed sub-block and an erased sub-block according to example embodiments.

Referring to FIG. 6, when a sub-block includes at least one erased page (erased word-line), the sub-block may be determined as an open sub-block OP_SB. The open sub-block OP_SB may include at least one erased page (erased word-line) and at least one valid page (programmed word-line).

When a sub-block includes only valid pages (programmed word-line) and does not include the erased page (erased word-line), the sub-block may be determined as a closed sub-block CL_SB. When a sub-block includes only the erased page (erased word-line), the sub-block may be determined as an erased sub-block ER_SB.

That is, each of the selected sub-block and the unselected sub-block according to example embodiments may be in (e.g., may have) the open state, the closed state or the erased state based on program progress state of each of the selected sub-block and the unselected sub-block.

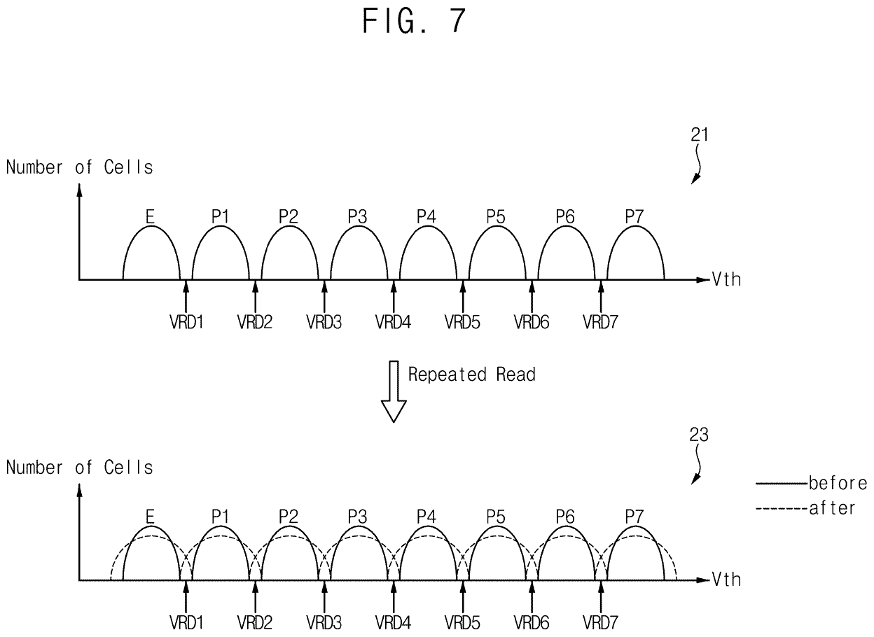

FIG. 7 is a graph showing a memory cell distribution change obtained through repetitive read operations.

Referring to FIG. 7, a reference numeral 21 corresponds to an initial memory cell distribution based on a threshold voltage, the horizontal axis indicates a threshold voltage “Vth”, and the vertical axis indicates the number of memory cells. For example, when a memory cell is a multi-level cell which is programmed by three bits, the memory cell may be in one of an erased state E, a first program state P1, a second program state P2, a third program state P3, a fourth program state P4, a fifth program state P5, a sixth program state P6 and a seventh program state P7.

For reading programmed data in the memory cells, the nonvolatile memory device 100 may use a plurality of read voltages VRD1, VRD2, VRD3, VRD4, VRD5, VRD6 and VRD7 and a read pass voltage VPASS. For example, for reading programmed data in the memory cells coupled to the selected word-line, the nonvolatile memory device 100 may sequentially apply one or more of the read voltages VRD1, VRD2, VRD3, VRD4, VRD5, VRD6 and VRD7 to the selected word-line and may apply the read pass voltage VPASS to the unselected word-lines. A voltage level of the read pass voltage VPASS may be greater than a voltage level of each of the read voltages VRD1, VRD2, VRD3, VRD4, VRD5, VRD6 and VRD7

A reference numeral 23 corresponds to a memory cell distribution obtained through changing by repetitive read operations, the horizontal axis indicates a threshold voltage “Vth”, and the vertical axis indicates the number of memory cells. During the read operation, because one or more of the read voltages VRD1, VRD2, VRD3, VRD4, VRD5, VRD6 and VRD7 is to the selected word-line and the read pass voltage VPASS is applied to the unselected word-lines, distributions of memory cells coupled to unselected word-lines of the selected sub-block and the unselected sub-block may be expanded and thus, error count may increase.

However, in a method of operating a storage controller according to example embodiments, the storage controller 50 may designate at least one word-line sensitive to read disturbance as additional target word-lines, among word-lines of the unselected sub-block in addition to target word-lines sensitive to read disturbance, among word-lines of the selected sub-block, may perform the reliability verification operation on the target word-lines and the additional target word-lines and may perform reclaim operation based on a result of the reliability verification operation. Therefore, the storage controller 50 may enhance reliability and performance.

FIG. 8 is a block diagram illustrating a storage device according to example embodiments.

Referring to FIG. 8, a storage device (i.e., a memory system) 10 may include a storage controller 50 and a nonvolatile memory device 100.

In example embodiments, each of the storage controller 50 and the nonvolatile memory device 100 may be provided with the form of a chip, a package, or a module. Alternatively, the storage controller 50 and the nonvolatile memory device 100 may be packaged into one of various packages.

The nonvolatile memory device 100 may perform an erase operation, a program operation or a write operation under control of the storage controller 50. The nonvolatile memory device 100 receives a command (signal) CMD, an address (signal) ADDR and data through input/output lines from the storage controller 50 for performing such operations. In addition, the nonvolatile memory device 100 may receive a control signal CTRL through a control line from the storage controller 50. In addition, the nonvolatile memory device 100 may receive a power PWR through a power line from the storage controller 50.

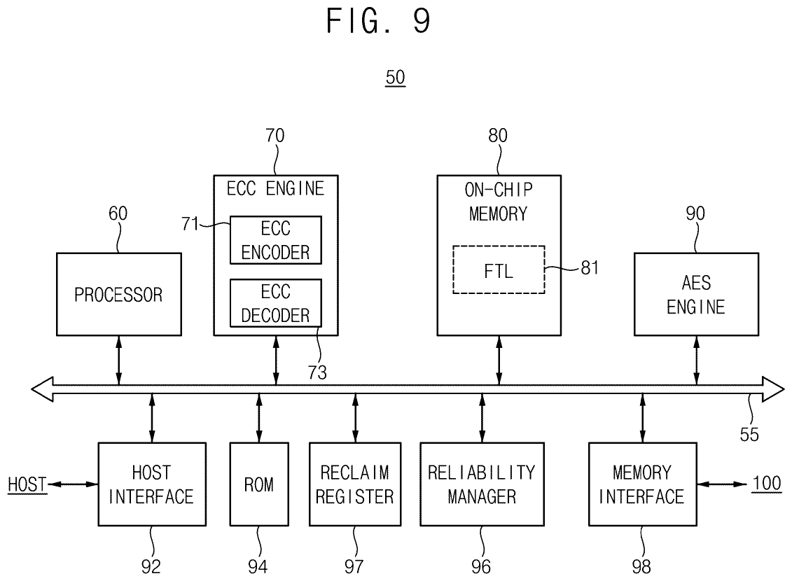

FIG. 9 is a block diagram illustrating an example of the storage controller in the storage device of FIG. 8 according to example embodiments.

Referring to FIG. 9, the storage controller 50 may include a processor 60, an error correction code (ECC) engine 70, an on-chip memory 80, an advanced encryption standard (AES) engine 90, a host interface 92, a ROM 94, a reliability manager 96, a reclaim register 97 and a memory interface 98 which are connected via a bus 55.

The processor 60 may control an overall operation of the storage controller 50. The processor 60 may control the ECC engine 70, the on-chip memory 80, the AES engine 90, the host interface 92, the ROM 94, the reliability manager 96, the reclaim register 97 and the memory interface 98. The processor 60 may include one or more cores (e.g., a homogeneous multi-core or a heterogeneous multi-core). The processor 60 may be or include, for example, at least one of a central processing unit (CPU), an image signal processing unit(ISP), a digital signal processing unit (DSP), a graphics processing unit(GPU), a vision processing unit (VPU), and a neural processing unit(NPU). The processor 60 may execute various application programs (e.g., a flash translation layer (FTL) 81 and firmware) loaded onto the on-chip memory 80.

The on-chip memory 80 may store various application programs that are executable by the processor 60. The on-chip memory 80 may operate as a cache memory adjacent to the processor 60. The on-chip memory 80 may store a command, an address, and data to be processed by the processor 60 or may store a processing result of the processor 60. The on-chip memory 80 may be, for example, a storage medium or a working memory including a latch, a register, a static random access memory(SRAM), a dynamic random access memory (DRAM), a thyristor random access memory (TRAM), a tightly coupled memory (TCM), etc.

The processor 60 may execute the FTL 81 loaded onto the on-chip memory 80. The FTL 81 may be loaded onto the on-chip memory 80 as firmware or a program stored in the nonvolatile memory device 100. The FTL 81 may manage mapping between a logical address provided from a host and a physical address of the nonvolatile memory device 100 and may include an address mapping table manager managing and updating an address mapping table. The FTL 81 may further perform a garbage collection operation, a wear leveling operation, and the like, as well as the address mapping described above. The FTL 81 may be executed by the processor 60 for addressing one or more of the following aspects of the nonvolatile memory device 100: overwrite-or in-place write-impossible, a life time of a memory cell, a limited number of program-erase (PE) cycles, and an erase speed slower than a write speed.

Memory cells of the nonvolatile memory device 100 may have the physical characteristic that a threshold voltage distribution varies due to causes, such as a program elapsed time, a temperature, program disturbance, read disturbance and etc. For example, data stored at the nonvolatile memory device 100 becomes erroneous due to the above causes.

The storage controller 50 may utilize a variety of error correction techniques to correct such errors. For example, the storage controller 50 may include the ECC engine 70. The ECC engine 70 may correct errors which occur in the data stored in the nonvolatile memory device 100. The ECC engine 70 may include an ECC encoder 71 and an ECC decoder 73. The ECC encoder 71 may perform an ECC encoding operation on data to be stored in the nonvolatile memory device 100. The ECC decoder 73 may perform an ECC decoding operation on data read from the nonvolatile memory device 100 in a normal read operation and in the reliability verification operation and may provide the processor 60 and/or the reliability manager 96 with an address of a word-line in which associated error count is greater than a reference error count based on a result of the ECC decoding.

The ROM 94 may store a variety of information, needed for the storage controller 50 to operate, in firmware.

The AES engine 90 may perform at least one of an encryption operation and a decryption operation on data input to the storage controller 50 by using a symmetric-key algorithm. Although not illustrated in detail, the AES engine 90 may include an encryption module and a decryption module. For example, the encryption module and the decryption module may be implemented as separate modules. For another example, one module capable of performing both encryption and decryption operations may be implemented in the AES engine 90.

The storage controller 50 may communicate with the host through the host interface 92. For example, the host interface 94 may include Universal Serial Bus (USB), Multimedia Card (MMC), embedded-MMC, peripheral component interconnection (PCI), PCI-express, Advanced Technology Attachment (ATA), Serial-ATA, Parallel-ATA, small computer small interface (SCSI), enhanced small disk interface (ESDI), Integrated Drive Electronics (IDE), Mobile Industry Processor Interface (MIPI), Nonvolatile memory express (NVMe), Universal Flash Storage (UFS), and etc. The storage controller 50 may communicate with the nonvolatile memory device 100 through the memory interface 98.

The reliability manager 96 may perform reliability verification operation on the target word-lines of the selected sub-block and the unselected sub-block and manage the reliability verification operation. As described with reference to FIG. 1, the reliability manager 96 may perform and/or manage the reliability verification operation by using the read disturbance level monitoring scheme or the OVS algorithm.

When an error count obtained through a result of the reliability verification operation is greater than a reference error count, the reliability manager 96 may register a corresponding sub-block in the reclaim register as a reclaimed sub-block directly or through the processor 60.

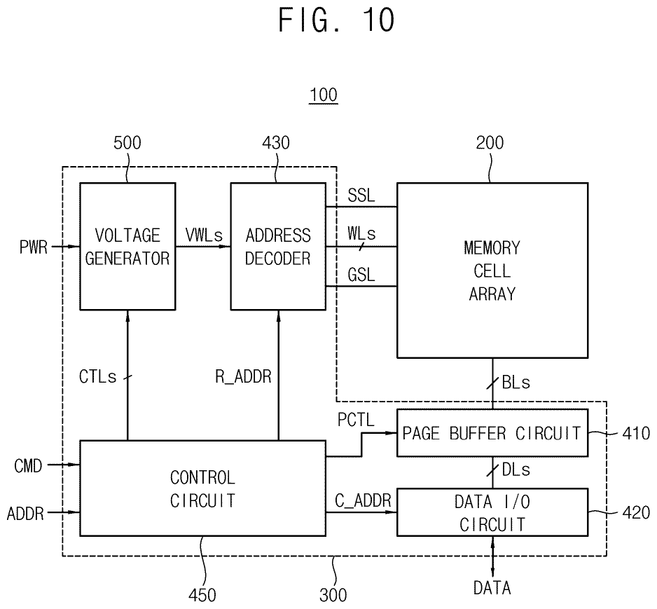

FIG. 10 is a block diagram illustrating an example of the nonvolatile memory device in the storage device of FIG. 8 according to example embodiments.

Referring to FIG. 10, the nonvolatile memory device 100 may include a memory cell array 200 and a peripheral circuit 300. The peripheral circuit 300 may include an address decoder 430, a page buffer circuit 410, a data input/output (I/O) circuit 420, a control circuit 450 and a voltage generator 500.

The memory cell array 200 may be coupled to the address decoder 430 through a string selection line SSL, a plurality of word-lines WLs, and a ground selection line GSL. In addition, the memory cell array 200 may be coupled to the page buffer circuit 410 through a plurality of bit-lines BLs. The memory cell array 200 may include a plurality of nonvolatile memory cells coupled to the plurality of word-lines WLs and the plurality of bit-lines BLs.

In some example embodiments, the memory cell array 200 may be a three-dimensional memory cell array, which is formed on a substrate in a three-dimensional structure (or a vertical structure). In this case, the memory cell array 200 may include vertical cell strings that are vertically oriented such that at least one memory cell is located over another memory cell.

The control circuit 450 may receive a command (signal) CMD and an address (signal) ADDR from the storage controller 50 and control an erase loop, a program loop and a read operation of the nonvolatile memory device 200 based on the command signal CMD and the address signal ADDR. The program loop may include a program operation and a program verification operation. The erase loop may include an erase operation and an erase verification operation. The read operation may include a normal read operation and reliability verification operation.

For example, the control circuit 450 may generate control signals CTLs to control the voltage generator 500 and may generate a page buffer control signal PCTL to control the page buffer circuit 410 based on the command signal CMD. The control circuit 450 may generate a row address R_ADDR and a column address C_ADDR based on the address signal ADDR. The control circuit 450 may provide the row address R_ADDR to the address decoder 430 and provide the column address C_ADDR to the data I/O circuit 420. The address signal ADDR or the row address R_ADDR may be referred to as an access address.

The address decoder 430 may be coupled to the memory cell array 200 through the string selection line SSL, the plurality of word-lines WLs, and the ground selection line GSL. During the program operation or the read operation, the address decoder 430 may determine one of the plurality of word-lines WLs as a selected word-line and determine rest of the plurality of word-lines WLs except for the selected word-line as unselected word-lines based on the row address R_ADDR.

The voltage generator 500 may generate word-line voltages VWLs, which are required for the operation of the nonvolatile memory device 200, based on the control signals CTLs. The voltage generator 500 may receive the power PWR from the storage controller 50. The word-line voltages VWLs may be applied to the plurality of word-lines WLs through the address decoder 430.

For example, during the erase operation, the voltage generator 500 may apply an erase voltage to a channel of cell strings of the memory block and may apply a ground voltage to word-lines of a sub-block to be erased. During the erase verification operation, the voltage generator 500 may apply an erase verification voltage to the word-lines of the sub-block to be erased or sequentially apply the erase verification voltage to word-lines in a word-line basis.

For example, during the program operation, the voltage generator 500 may apply a program voltage to the selected word-line and may apply a program pass voltage to the unselected word-lines. In addition, during the program verification operation, the voltage generator 500 may apply a program verification voltage to the selected word-line and may apply a verification pass voltage to the unselected word-lines.

The page buffer circuit 410 may be coupled to the memory cell array 200 through the plurality of bit-lines BLs. The page buffer circuit 410 may include a plurality of page buffers. The page buffer circuit 410 may temporarily store data to be programmed in a selected page or data read out from the selected page.

The data I/O circuit 420 may be coupled to the page buffer circuit 410 through a plurality of data lines DLs. During the program operation, the data I/O circuit 420 may receive program data from the storage controller 50 and provide the program data DATA to the page buffer circuit 410 based on the column address C_ADDR received from the control circuit 450. During the read operation, the data I/O circuit 420 may provide read data DATA, which are stored in the page buffer circuit 410, to the storage controller 50 based on the column address C_ADDR received from the control circuit 450.

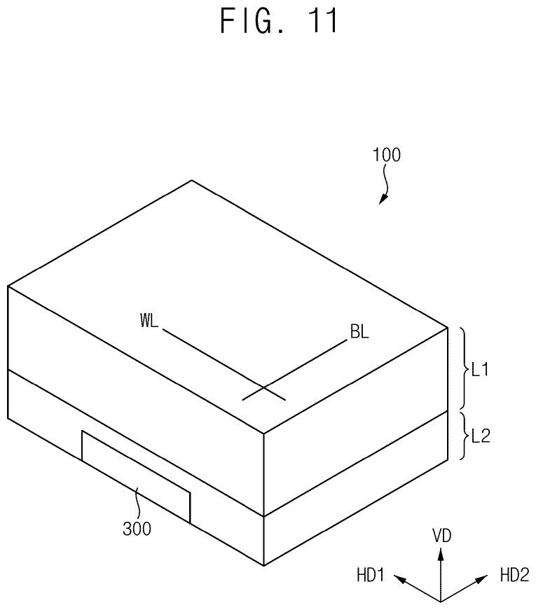

FIG. 11 schematically illustrates a structure of the nonvolatile memory device of FIG. 10 according to example embodiments.

Referring to FIG. 11, the nonvolatile memory device 100 may include a first semiconductor layer L1 and a second semiconductor layer L2, and the first semiconductor layer L1 may be stacked in a vertical direction VD with respect to the second semiconductor layer L2. The second semiconductor layer L2 may be under the first semiconductor layer L1 in the vertical direction VD, and accordingly, the second semiconductor layer L2 may be close to a substrate.

In example embodiments, the memory cell array 200 in FIG. 10 may be formed (or, provided) on the first semiconductor layer L1, and the peripheral circuit 300 in FIG. 10 may be formed (or, provided) on the second semiconductor layer L2. Accordingly, the nonvolatile memory device 100 may have a structure in which the memory cell array 200 is on the peripheral circuit 300, that is, a cell over periphery (COP) structure. The COP structure may effectively reduce an area in a horizontal direction and improve the degree of integration of the nonvolatile memory device 100.

In example embodiments, the second semiconductor layer L2 may include the substrate, and by forming transistors on the substrate and metal patterns for wiring transistors, the peripheral circuit 300 may be formed in the second semiconductor layer L2. After the peripheral circuit 300 is formed on the second semiconductor layer L2, the first semiconductor layer L1 including the memory cell array 200 may be formed, and the metal patterns for connecting the word-lines WL and the bit-lines BL of the memory cell array 200 to the peripheral circuit 200 formed in the second semiconductor layer L2 may be formed. For example, the word-lines WL may extend in a first horizontal direction HD1 and the bit-lines BL may extend in a second horizontal direction HD2.

As the number of stages of memory cells in the memory cell array 200 increases with the development of semiconductor processes, that is, as the number of stacked word-lines WL increases, an area of the memory cell array 200 may decrease, and accordingly, an area of the peripheral circuit 300 may also be reduced. According to an embodiment, to reduce an area of a region occupied by the page buffer circuit 410, the page buffer circuit 410 may have a structure in which the page buffer unit and the cache latch are separated from each other, and may connect sensing nodes included in each of the page buffer units commonly to a combined sensing node.

FIG. 12 is a block diagram illustrating an example of the memory cell array in the nonvolatile memory device of FIG. 10 according to example embodiments.

Referring to FIG. 12, the memory cell array 200 may include a plurality of memory blocks BLK1 to BLKz. Here, z is a natural number greater than two. The memory blocks BLK1 to BLKz extend along the first horizontal direction HD1, the second horizontal direction HD2, and the vertical direction VD. In some example embodiments, the memory blocks BLK1 to BLKz are selected by the address decoder 430 in FIG. 10. For example, the address decoder 430 may select a memory block BLK corresponding to a block address among the memory blocks BLK1 to BLKz.

The first horizontal direction HD1 and the second horizontal direction HD2 cross each other and are substantially parallel to an upper surface to a substrate and the vertical direction VD is substantially perpendicular to the upper surface of the substrate.

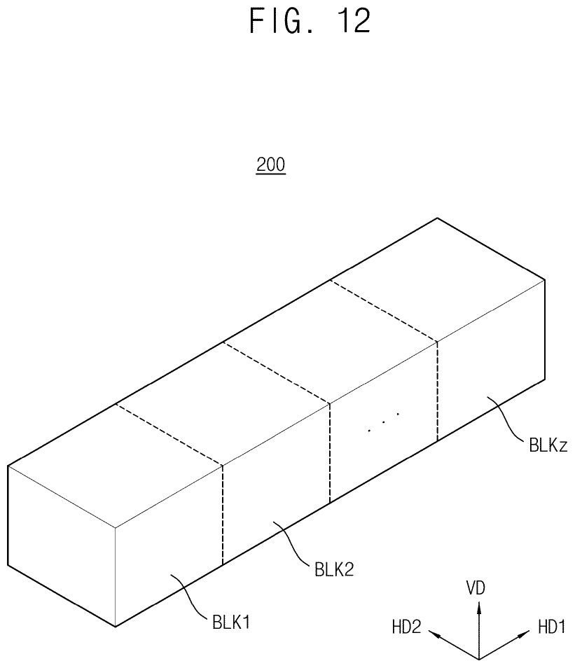

FIG. 13 is a circuit diagram illustrating one of the memory blocks of FIG. 12 according to example embodiments.

A memory block BLKi of FIG. 13 may be formed on a substrate SUB in a three-dimensional structure (or a vertical structure). Here, i may be one of 1 to z. For example, a plurality of memory cell strings included in the memory block BLKi may be formed in the vertical direction VD perpendicular to the substrate SUB.

Referring to FIG. 13, the memory block BLKi may include a plurality of (memory) cell strings NS11, NS21, NS31, NS12, NS22, NS32, NS13, NS23 and NS33 (which are hereinafter represented by NS11 to NS33) coupled between bit-lines BL1, BL2 and BL3 and a common source line CSL. Each of the cell strings NS11 to NS33 may include a string selection transistor SST, a plurality of memory cells MC1, MC2, MC3, MC4, MC4, MC5, MC6, MC7, MC8, MC9, MC10, MC11 and MC12 (which are hereinafter represented by MC1 to MC12), and a ground selection transistor GST.

The string selection transistor SST may be connected to corresponding string selection lines SSL1, SSL2 and SSL3 (which are hereinafter represented by SSL1 to SSL3). The plurality of memory cells MC1 to MC12 may be connected to corresponding word-lines WL1, WL2, WL3, WL4, WL5, WL6, WL7, WL8, WL9, WL10, WL11 and WL12 (which are hereinafter represented by WL1 to WL12), respectively. The ground selection transistor GST may be connected to corresponding ground selection lines CSL1, CSL2 and GSL3 (which are hereinafter represented by GSL1 to GSL3). The string selection transistor SST may be connected to corresponding bit-lines BL1, BL2 and BL3, and the ground selection transistor GST may be connected to the common source line CSL.

Word-lines (e.g., word-line WL1) having the same height may be commonly connected, and the ground selection lines GSL1 to GSL3 and the string selection lines SSL1 to SSL3 may be separated.

According to some embodiments, the memory block BLKi may be divided into a plurality of sub-blocks, indicated by representative sub-blocks SB1, SB2, and SB3, each sub-block being smaller in size than the memory block BLKi. The sub-blocks SB1, SB2 and SB3 may be divided in a word-line direction, as shown in FIG. 13. In some embodiments, the sub-blocks SB1, SB2 and SB3 may be divided on the basis of bit-lines or string selection lines. The sub-blocks SB1, SB2 and SB3 in the memory block BLKi may be erased independently of the reference used to divide the memory block BLKi into sub-blocks.

For example, the sub-block SB1 includes memory cells coupled to the word-lines WL1, WL2, WL3 and WL4, the sub-block SB2 includes memory cells coupled to the word-lines WL5, WL6, WL7 and WL8, and the sub-block SB3 includes memory cells coupled to the word-lines WL9, WL10, WL11 and WL12, from among the memory cells included in the memory block BLKi. The memory cells included in the sub-block SB1 may be selected and erased independently of the remaining sub-blocks SB2 and SB3, and vice versa. One or more of the sub-blocks SB1, SB2, and SB3 may be selected and erased at the same time or at different times. The address decoder 430 in FIG. 11 may provide a bias for erasing memory cells by sub-block unit.

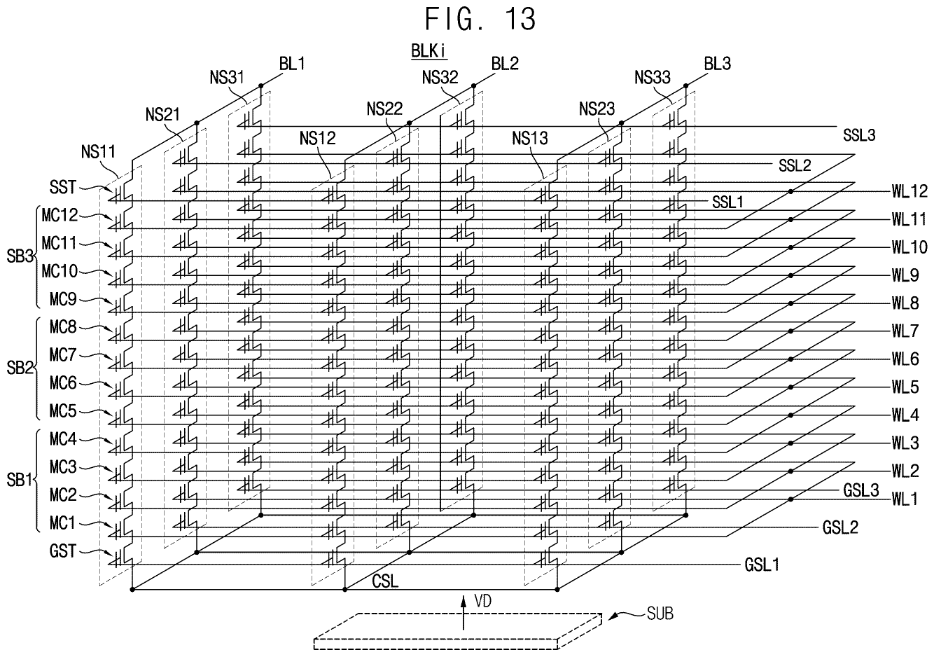

FIG. 14 illustrates an example of a structure of a cell string in the memory block of FIG. 13.

Referring to FIGS. 13 and 14, a pillar PL is provided on the substrate SUB such that the pillar PL extends in a direction perpendicular to the substrate SUB to make contact with the substrate SUB. Each of the ground selection line GSL, the word-lines WL1 to WL12, and the string selection lines SSL illustrated in FIG. 14 may be formed of a conductive material parallel with the substrate SUB, for example, a metallic material. The pillar PL may be in contact with the substrate SUB through the conductive materials forming the string selection lines SSL1, the word-lines WL1 to WL12, and the ground selection line GSL1. The sub-block SB1 may include memory cells coupled to the word-lines WL1, WL2, WL3 and WL4. The sub-block SB3 may include memory cells coupled to the word-lines WL9, WL10, WL11 and WL12.

A sectional view taken along a line E-E′ is also illustrated in FIG. 14. In some example embodiments, a sectional view of a first memory cell MC1 corresponding to a first word-line WL1 is illustrated. The pillar PL may include a cylindrical body BD. An air gap AG may be defined in the interior of the body BD.

The body BD may include P-type silicon and may be an area where a channel will be formed. The pillar PL may further include a cylindrical tunnel insulating layer TI surrounding the body BD and a cylindrical charge trap layer CT surrounding the tunnel insulating layer TI. A blocking insulating layer BI may be provided between the first word-line WL1 and the pillar PL. The body BD, the tunnel insulating layer TI, the charge trap layer CT, the blocking insulating layer BI, and the first word-line WL1 may constitute or be included in a charge trap type transistor that is formed in a direction perpendicular to the substrate SUB or to an upper surface of the substrate SUB. A string selection transistor SST, a ground selection transistor GST, and other memory cells may have the same structure as the first memory cell MC1.

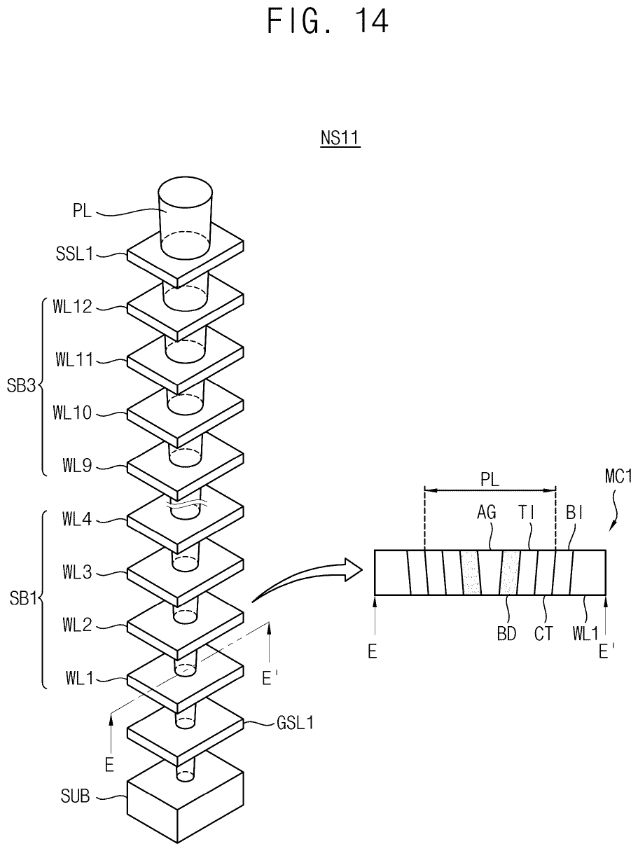

FIG. 15 is a block diagram illustrating the control circuit in the nonvolatile memory device of FIG. 10 according to example embodiments.

Referring to FIG. 15, the control circuit 450 may include a command decoder 460, an address buffer 470, a control signal generator 480 and a status signal generator 485.

The command decoder 460 may decode the command CMD and may provide a decoded command D_CMD to the control signal generator 480 and the status signal generator 485.

The address buffer 470 may receive the address (signal) ADDR, provide the row address R_ADDR to the address decoder 430 and provide the column address C_ADDR to the data I/O circuit 420.

The control signal generator 480 may receive the decoded command D_CMD, generate the control signals CTLs based on an operation directed by the decoded command D_CMD, provide the control signals CTLs to the voltage generator 500, generate the page buffer control signal PCTL, and provide the page buffer control signal PCTL to the page buffer circuit 410.

The status signal generator 485 may receive the decoded command D_CMD, monitor operation directed by the decoded command D_CMD and may transit a status signal nR/B to a ready state or a busy state based on whether the operation directed by the decoded command D_CMD is completed.

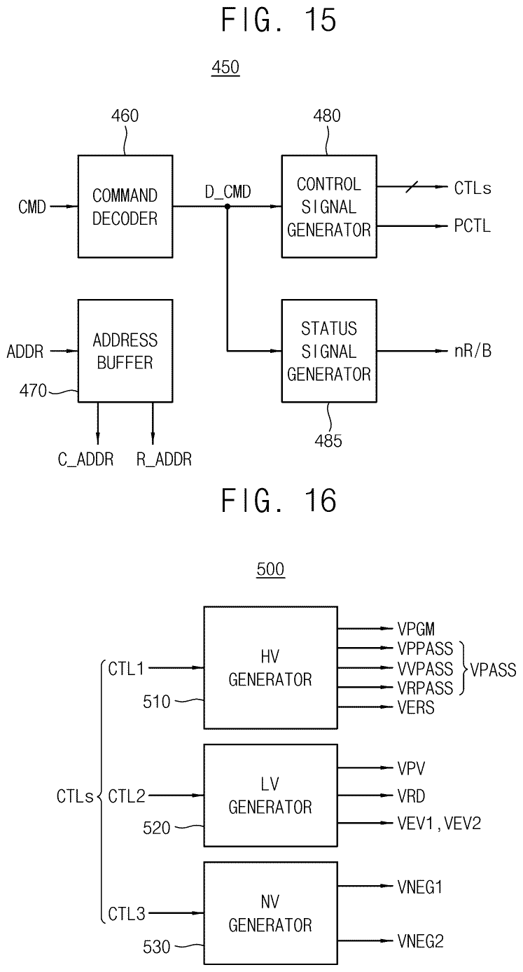

FIG. 16 is a block diagram illustrating an example of the voltage generator in the nonvolatile memory device of FIG. 10 according to example embodiments.

Referring to FIG. 16, the voltage generator 500 may include a high voltage HV generator 510 and a low voltage LV generator 520. The voltage generator 500 may further include a negative voltage NV generator 530.

The high voltage generator 510 may generate a program voltage PGM, a program pass voltage VPPASS, a verification pass voltage VVPASS, a read pass voltage VRPASS and an erase voltage VERS according to operations directed by the command CMD, in response to a first control signal CTL1. The program pass voltage VPPASS, the verification pass voltage VVPASS and the read pass voltage VRPASS may be included in the pass voltage VPASS.

The program voltage VPGM may be applied to the selected word-line, the program pass voltage VPPASS, the verification pass voltage VVPASS, the read pass voltage VRPASS may be applied to the unselected word-lines, and the erase voltage VERS may be applied to a channel of a cell string. The first control signal CTL1 may include a plurality of bits which indicate the operations directed by the decoded command D_CMD.

The low voltage generator 520 may generate a program verification voltage VPV, an erase verification voltage VER, a read voltage VRD and erase verification voltages VEV1 and VEV2 according to operations directed by the command CMD, in response to a second control signal CTL2.

The program verification voltage VPV, the read voltage VRD, and erase verification voltages VEV1 and VEV2 may be applied to word-lines of the selected sub-block according to operation of the nonvolatile memory device 100. The second control signal CTL2 may include a plurality of bits which indicate the operations directed by the decode command D_CMD.

The negative voltage generator 530 may generate a first negative voltage VNEG1 and a second negative voltage VNEG2 which have negative levels according to operations directed by the command CMD, in response to a third control signal CTL3. The third control signal CTL3 may include a plurality of bits which indicate the operations directed by the decoded command D_CMD. The first negative voltage VNEG1 and the second negative voltage VNEG2 may be used for the program operation.

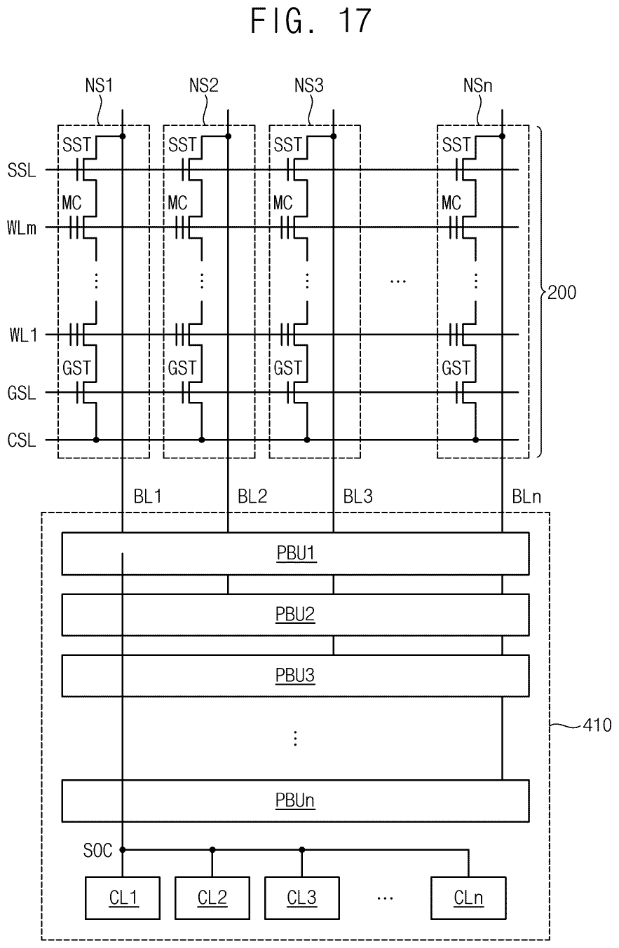

FIG. 17 is a schematic diagram of a connection of the memory cell array and the page buffer circuit in FIG. 10, according to example embodiments.

Referring to FIG. 17, the memory cell array 200 may include first through n-th cell strings NS1, NS2, NS3, . . . , NSn, each of the first through n-th cell strings NS1, NS2, NS3, . . . , NSn may include a ground select transistor GST connected to the ground select line GSL, a plurality of memory cells MC respectively connected to the first through m-th word-lines WL1, . . . , WLm, and a string select transistor SST connected to the string select line SSL, and the ground select transistor GST, the plurality of memory cells MC, and the string select transistor SST may be connected to each other in series. In this case, n may be an integer greater than three and m may be a positive integer.

The page buffer circuit 410 may include first through n-th page buffer units PBU1, PBU2, PBU3, . . . , PBUn. The first page buffer unit PB1 may be connected to the first cell string NS1 via the first bit-line BL1, and the n-th page buffer unit PBUn may be connected to the n-th cell string NSn via the n-th bit-line BLn. In this case, n may be a positive integer. For example, n may be 8, and the page buffer circuit 410 may have a structure in which page buffer units of eight stages, or, the first through n-th page buffer units PBU1, PBU2, PBU3, . . . , PBUn are in a line. For example, the first through n-th page buffer units PBU1, PBU2, PBU3, . . . , PBUn may be in a row in an extension direction of the first through n-th bit-lines BL1, BL2, BL3, . . . , BLn.

The page buffer circuit 410 may further include first through n-th cache latches CL1, CL2, CL3, . . . , CLn respectively corresponding to the first through n-th page buffer units PBU1, PBU2, PBU3, . . . , PBUn. For example, the page buffer circuit 410 may have a structure in which the cache latches of eight stages or the first through n-th cache latches CL1, CL2, CL3, . . . , CLn in a line. For example, the first through n-th cache latches CL1, CL2, CL3, . . . , CLn may be in a row in an extension direction of the first through n-th bit-lines BL1, BL2, BL3, . . . , BLn.

The sensing nodes of each of the first through n-th page buffer units PBU1, PBU2, PBU3, . . . , PBUn may be commonly connected to a combined sensing node SOC. In addition, the first through n-th cache latches CL1, CL2, CL3, . . . , CLn may be commonly connected to the combined sensing node SOC. Accordingly, the first through n-th page buffer units PBU1, PBU2, PBU3, . . . , PBUn may be connected to the first through n-th cache latches CL1, CL2, CL3, . . . , CLn via the combined sensing node SOC.

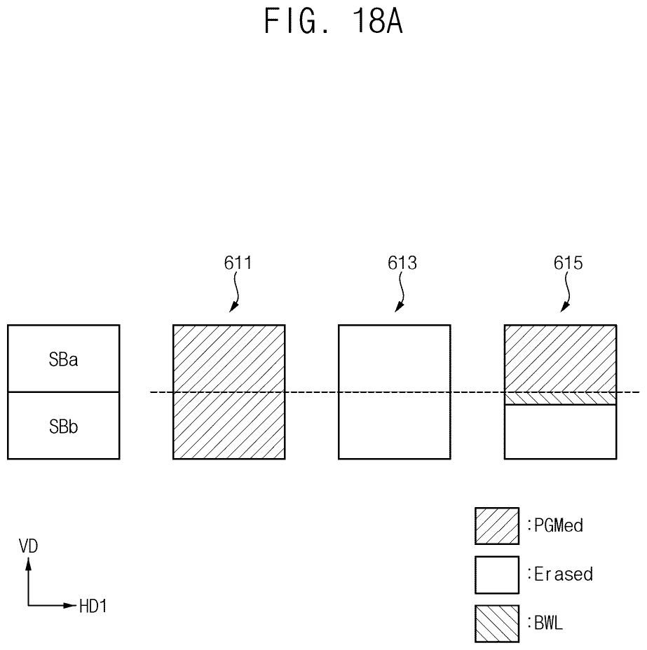

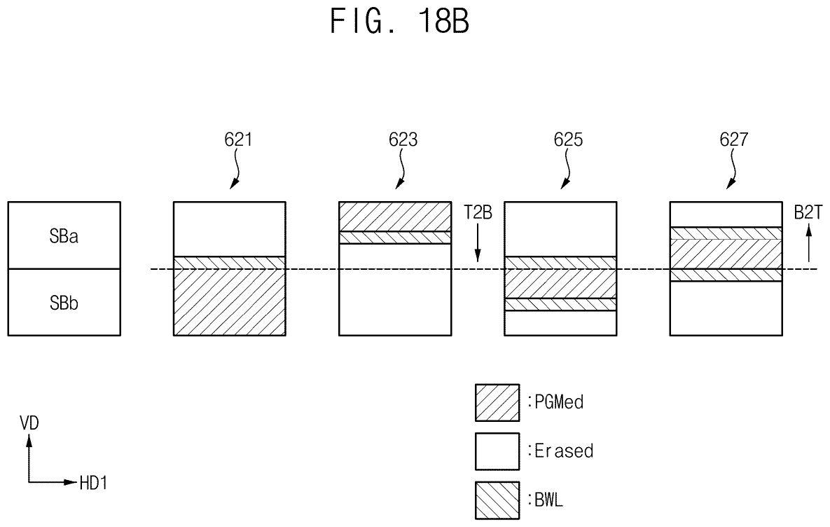

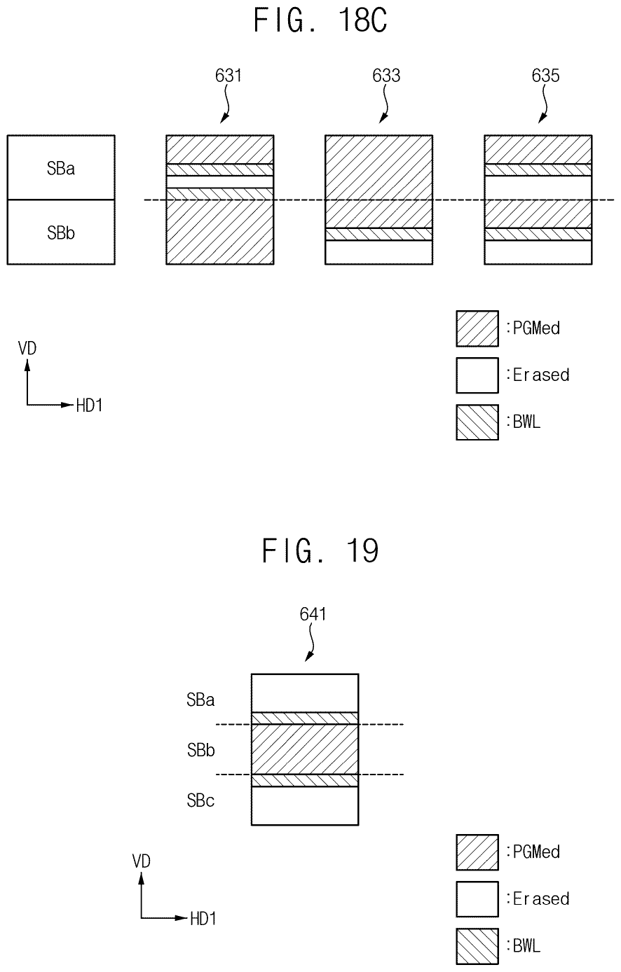

FIGS. 18A, 18B and 18C illustrate a position of a boundary word-line based on program progress states of a selected sub-block and an unselected sub-block, respectively, according to example embodiments.

A boundary word-line may be a word-line physically adjacent to a programmed word-line.

In each of FIGS. 18A, 18B and 18C, assuming that a specific memory block is divided into a first sub-block SBa and a second sub-block SBb, the first sub-block SBa is a selected sub-block, the second sub-block SBb is an unselected sub-block and the first sub-block SBa is stacked on the second sub-block SBb in the vertical direction VD.

Referring to FIG. 18A, when the first sub-block SBa and the second sub-block SBb are in closed state (e.g., programmed state) as a reference numeral 611 indicates, a boundary word-line BWL does not exist.

In addition, when the first sub-block SBa and the second sub-block SBb are in erased state as a reference numeral 613 indicates, a boundary word-line BWL does not exist.

In addition, when the first sub-block SBa is in closed state and the second sub-block SBb is in erased state as a reference numeral 615 indicates, a word-line physically adjacent to programmed word-lines of the first sub-block SBa among second word-lines of the second sub-block SBb may correspond to a boundary word-line BWL. That is, the uppermost word-line among the second word-lines of the second sub-block SBb may correspond to the boundary word-line BWL.

Referring FIG. 18B, when the first sub-block SBa is in erased state and the second sub-block SBb is in closed state as a reference numeral 621 indicates, a word-line physically adjacent to programmed word-lines of the second sub-block SBb among first word-lines of the first sub-block SBa may correspond to a boundary word-line BWL. That is, the lowermost word-line among the first word-lines of the first sub-block SBa may correspond to the boundary word-line BWL.

In addition, when the first sub-block SBa is in open state (e.g., a portion of first word-lines of the first sub-block SBa are programmed) and the second sub-block SBb is in erased state as a reference numeral 623 indicates, an erased word-line physically adjacent to programmed word-lines of the first sub-block SBa may correspond to a boundary word-line BWL. That is, the uppermost erased word-line among the erased word-lines of the first sub-block SBa may correspond to the boundary word-line BWL.

In addition, when the first sub-block SBa is in erased state and the second sub-block SBb is in open state as a reference numeral 625 indicates, an erased word-line physically adjacent to programmed word-lines among erased word-lines of the second sub-block SBb and a word-line physically adjacent to programmed word-lines of the second sub-block SBb among the first word-lines of the first memory block SBa may correspond to a boundary word-line BWL. That is, the uppermost erased word-line among the erased word-lines of the second sub-block SBb and the lowermost word-line among the first word-line of the first sub-block SBa may correspond to the boundary word-line BWL.

In addition, when the first sub-block SBa is in open state and the second sub-block SBb is in erased state as a reference numeral 627 indicates, an erased word-line physically adjacent to programmed word-lines of the first sub-block SBa among erased word-lines of the first memory block SBa and a word-line physically adjacent to programmed word-lines of the first sub-block SBa among the second word-lines of the second memory block SBb may correspond to a boundary word-line BWL. That is, the lowermost erased word-line among the erased word-lines of the first sub-block SBa and the uppermost word-line among the second word-line of the second sub-block SBb may correspond to the boundary word-line BWL.

In FIG. 18B, the reference numerals 623 and 625 may correspond to a T2B program scheme in which a program operation is performed from the uppermost word-line of the sub-block to the lowermost word-line of the sub-block and the reference numeral 627 may correspond to a B2T program scheme in which a program operation is performed from the lowermost word-line of the sub-block to the uppermost word-line of the sub-block. That is, the position of the boundary word-line BWL may vary based on a program order.

Referring to FIG. 18C, when the first sub-block SBa is in open state (e.g., a portion of first word-lines of the first sub-block SBa are programmed) and the second sub-block SBb is in closed state as a reference numeral 631 indicates, an erased word-line physically adjacent to programmed word-lines of the first sub-block SBa and an erased word-line physically adjacent to programmed word-lines of the second sub-block SBb among the erased word-lines of the first sub-block SBa may correspond to a boundary word-line BWL. That is, the uppermost erased word-line and the lowermost word-line among the erased word-lines of the first sub-block SBa may correspond to the boundary word-line BWL.

When the first sub-block SBa is in closed state and the second sub-block SBb is in open state (e.g., a portion of second word-lines of the second sub-block SBa are programmed) as a reference numeral 633 indicates, an erased word-line physically adjacent to programmed word-lines of the second sub-block SBa among erased word-lines of the second sub-block SBa may correspond to a boundary word-line BWL. That is, the uppermost erased word-line among the erased word-lines of the second sub-block SBb may correspond to the boundary word-line BWL.

When the first sub-block SBa is in closed state and the second sub-block SBb is in open state (e.g., a portion of second word-lines of the second sub-block SBa are programmed) as a reference numeral 633 indicates, an erased word-line physically adjacent to programmed word-lines of the second sub-block SBb among erased word-lines of the second sub-block SBb may correspond to a boundary word-line BWL. That is, the uppermost erased word-line among the erased word-lines of the second sub-block SBb may correspond to the boundary word-line BWL.

When the first sub-block SBa and the second sub-block SBb are in open state (e.g., a portion of first word-lines of the first sub-block SBa are programmed and a portion of second word-lines of the second sub-block SBb are programmed) as a reference numeral 635 indicates, an erased word-line physically adjacent to programmed word-lines of the first sub-block SBa among erased word-lines of the first sub-block SBa and an erased word-line physically adjacent to programmed word-lines of the second sub-block SBb among erased word-lines of the second sub-block SBb may correspond to a boundary word-line BWL. That is, the uppermost erased word-line among the erased word-lines of the first sub-block SBa and the uppermost erased word-line among the erased word-lines of the second sub-block SBb may correspond to the boundary word-line BWL.

FIG. 19 illustrates a position of a boundary word-line based on program progress states of a selected sub-block and an unselected sub-block according to example embodiments.

In FIG. 19, assuming that a specific memory block is divided into a first sub-block SBa, a second sub-block SBb and a third sub-block SBc, the first sub-block SBa is stacked on the second sub-block SBb in the vertical direction VD and the second sub-block SBb is stacked on the third sub-block SBc in the vertical direction VD.

Referring to FIG. 19, when the first sub-block SBa and the third sub-block SBc are in erased state and the second sub-block SBb is in closed state as a reference numeral 641 indicates, a word-line physically adjacent to programmed word-lines of the second sub-block SBb among first word-lines of the first sub-block SBa and a word-line physically adjacent to programmed word-lines of the second sub-block SBb among third word-lines of the third sub-block SBc may correspond to a boundary word-line BWL. That is, the lowermost word-line among the first word-lines of the first sub-block SBa and the uppermost word-line among the third word-lines of the third sub-block SBc may correspond to the boundary word-line BWL.

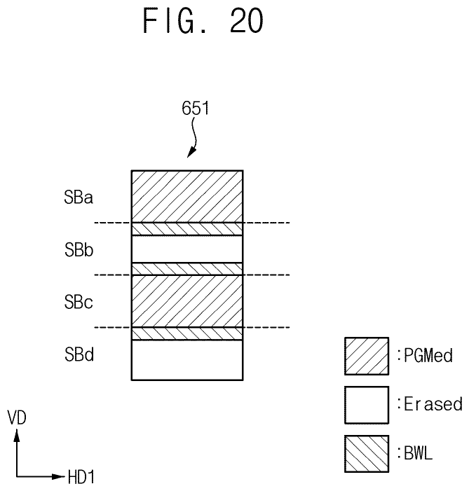

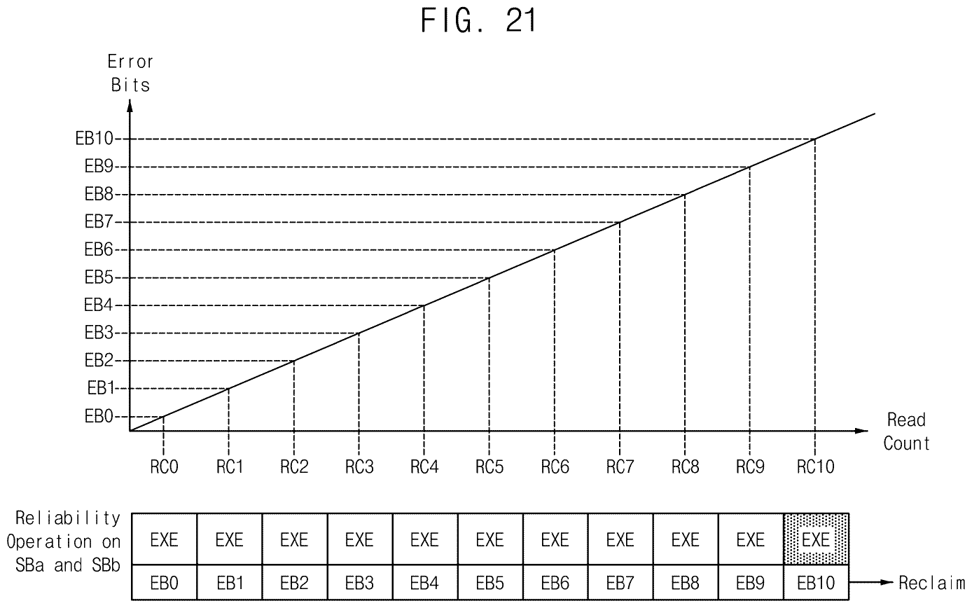

FIG. 20 illustrates a position of a boundary word-line based on program progress states of a selected sub-block and an unselected sub-block according to example embodiments.

In FIG. 20, assuming that a specific memory block is divided into a first sub-block SBa, a second sub-block SBb, a third sub-block SBc and a fourth sub-block SBd, the first sub-block SBa is stacked on the second sub-block SBb in the vertical direction VD, the second sub-block SBb is stacked on the third sub-block SBc in the vertical direction VD and the third sub-block SBc is stacked on the fourth sub-block SBd in the vertical direction VD.

Referring to FIG. 20, when the first sub-block SBa and the third sub-block SBc are in closed state and the second sub-block SBb and the fourth sub-block SBd are in erased state as a reference numeral 651 indicates, a word-line physically adjacent to programmed word-lines of the first sub-block SBa among second word-lines of the second sub-block SBb, a word-line physically adjacent to programmed word-lines of the third sub-block SBc among the second word-lines of the second sub-block SBb and a word-line physically adjacent to programmed word-lines of the third sub-block SBc among fourth word-lines of the fourth sub-block SBd may correspond to boundary word-line BWL. That is, the uppermost word-line and the lowermost word-line among the second word-lines of the second sub-block SBb and the uppermost word-line among the fourth word-lines of the fourth sub-block SBd may correspond to the boundary word-line BWL.

When a specific memory block is divided into three or more sub-blocks as described with reference to FIGS. 19 and 20, the storage controller 50 or the reliability manager 96 may designate an adjacent word-line and a weak word-line of the selected sub-block and an adjacent word-line and a weak word-line of each of the unselected sub-blocks as target word-lines and may perform the reliability verification operation on the target word-lines according to an order from the selected sub-block to the unselected sub-blocks.

FIG. 21 is a diagram for describing an operating characteristic and a reliability verification operation of a memory block of FIG. 13.

In a graph portion of FIG. 21, a horizontal axis represents a read count of the memory block BLKi, and a vertical axis represents the number of error bits (e.g., the error count) occurring in the memory block BLKi. In an embodiment, the read count may indicate the number of times that a read operation is performed on the memory block BLKi.

In the below-described embodiment, for convenience of description, it may be assumed that a ratio of the read count of the memory block BLKi and error bits are linear. However, the present disclosure is not limited thereto. For example, a ratio of an actual read count and actual error bits may be non-linear depending on the physical characteristics and/or a degradation state of the memory block BLKi, without limitation thereto. In addition, it is assumed that the memory block BLKi is divided into sub-blocks SBa and SBb.

In addition, the number of error bits (e.g., the error count) detected through the reliability verification operation of the memory block BLKi may be referred to as “error information”. For example, the storage controller 50 may perform the reliability verification operation on the memory block BLKi to obtain the error information indicating the number of error bits included in the memory block BLKi, without limitation thereto.

Moreover, it may be assumed that the reliability manager 96 of the storage controller 50 performs the reliability verification operation on the memory block BLKi depending on the given interval (e.g., uniform interval). However, the present disclosure is not limited thereto. For example, the reliability verification operation may be performed on the memory block BLKi non-periodically, depending on the operating state of the storage device 10. As an example, the reliability verification operation may be performed on the memory block BLKi at arbitrary intervals or random intervals. In this case, an average of the arbitrary intervals may correspond to the given interval, without limitation thereto.

Referring to FIGS. 9 and 21, the storage controller 50 may repeatedly perform the read operation EXE on the memory block BLKi, and thus, the read count of the memory block BLKi may increase. In this case, error bits (e.g., the error count) of the memory block BLKi may increase, such as due to read disturbances associated with the repeatedly performed read operation.

To guarantee the reliability of data stored in the memory block BLKi, the storage controller 50 or the reliability manager 96 may perform the reliability verification operation at the given interval. For example, when the number of times that the read operation of the memory block BLKi has been repeated matches a 0-th read count RC0, the storage controller 50 or the reliability manager 96 may perform the reliability (verification) operation on the memory block BLKi. In this case, 0-th error information EB0 of the memory block BLKi may be obtained.

Moreover, the storage controller 50 or the reliability manager 96 may perform the reliability verification operation when the number of times that the read operation of the memory block BLKi has been repeated reaches first to tenth read counts RC1 to RC10 of the first memory block BLKi. As the reliability verification operation is performed at each of the first to tenth read counts RC1 to RC10, first to tenth error information EB1 to EB10 of the memory block BLKi may be obtained, respectively.

In an embodiment, through the reliability verification operation performed at the tenth read count RC10 of the memory block BLKi, it may be determined that the memory block BLKi includes error bits corresponding to the tenth error information EB10. In this case, the number of error bits corresponding to the tenth error information EB10 may correspond to a level exceeding a reclaim reference of the memory block BLK1, above which level the block may be reclaimed. As such, the reliability manager 96 may correct an error of the data stored in the memory block BLKi and may program the corrected data in another memory block. A series of operations as described above may be called a “reclaim operation”.

As described above, the reliability manager 96 may determine the error level of the memory block BLKi by performing the reliability verification operation on the memory block BLKi every given interval; when the error level (e.g., the error count) of the memory block BLKi or the sub-block SBa exceeds (e.g., is greater than) a preset threshold value (e.g., a reference error count), the reliability manager 96 may perform the reclaim operation on the memory block BLKi or the sub-block SBa.

Therefore, the storage device according to example embodiments, may designate at least one word-line sensitive to read disturbance as additional target word-lines, among word-lines of the unselected sub-block in addition to target word-lines sensitive to read disturbance, among word-lines of the selected sub-block, may perform the reliability verification operation on the target word-lines and the additional target word-lines and may perform reclaim operation based on a result of the reliability verification operation. Therefore, the storage device may enhance reliability and performance.

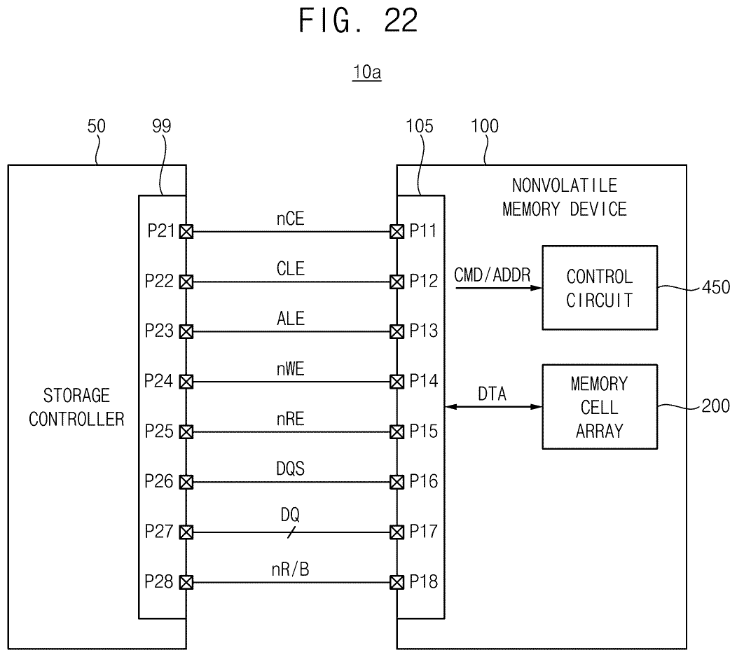

FIG. 22 illustrates a connection example of a storage controller and a nonvolatile memory device in the storage device of FIG. 8 according to example embodiments.

Referring to FIG. 22, the storage device 10a may include a nonvolatile memory device 100 and a storage controller 50. FIG. 22 illustrates an interface between the nonvolatile memory device 100 and the storage controller 50 in detail.

The nonvolatile memory device 100 may include first to eighth pins P11, P12, P13, P14, P15, P16, P17 and P18, an interface circuit 105, a control circuit 450 and a memory cell array 200. The interface circuit 105 may be referred to as a first interface circuit or a memory interface circuit.

The interface circuit 105 may receive a chip enable signal nCE from the storage controller 50 through the first pin P11. The interface circuit 105 may transmit and receive signals to and from the storage controller 50 through the second to eighth pins P12 to P18 in response to the chip enable signal nCE. For example, when the chip enable signal nCE is in an enable state (e.g., a low level), the interface circuit 105 may transmit and receive signals to and from the storage controller 50 through the second to eighth pins P12 to P18.

The interface circuit 105 may receive a command latch enable signal CLE, an address latch enable signal ALE and a write enable signal nWE from the storage controller 50 through the second to fourth pins P12 to P14. The interface circuit 105 may receive a data signal DQ from the storage controller 50 through the seventh pin P17 or may transmit the data signal DQ to the storage controller 50. A command CMD, an address ADDR and data DTA may be transmitted via the data signal DQ. For example, the data signal DQ may be transmitted through a plurality of data signal lines. In this case, the seventh pin P17 may include a plurality of pins respectively corresponding to a plurality of data signals DQ(s).

The interface circuit 105 may obtain the command CMD from the data signal DQ, which is received in an enable section (e.g., a high-level state) of the command latch enable signal CLE based on toggle time points of the write enable signal nWE. The interface circuit 105 may obtain the address ADDR from the data signal DQ, which is received in an enable section (e.g., a high-level state) of the address latch enable signal ALE based on the toggle time points of the write enable signal nWE.

In some example embodiments, the write enable signal nWE may be maintained at a static state (e.g., a high level or a low level) and may toggle between the high level and the low level. For example, the write enable signal nWE may toggle in a section in which the command CMD or the address ADDR is transmitted. Thus, the interface circuit 105 may obtain the command CMD or the address ADDR based on the toggle time points of the write enable signal nWE.

The interface circuit 105 may receive a read enable signal nRE from the storage controller 50 through the fifth pin P15. The interface circuit 105 may receive a data strobe signal DQS from the storage controller 50 through the sixth pin P16 or may transmit the data strobe signal DQS to the storage controller 50.

In a data output operation of the nonvolatile memory device 100, the interface circuit 105 may receive the read enable signal nRE, which toggles through the fifth pin P15, before outputting the data DTA. The interface circuit 105 may generate the data strobe signal DQS, which toggles based on the toggling of the read enable signal nRE. For example, the interface circuit 105 may generate the data strobe signal DQS, which starts toggling after a predetermined delay (e.g., tDQSRE), based on a toggling start time of the read enable signal nRE. The interface circuit 105 may transmit the data signal DQ including the data DTA based on a toggle time point of the data strobe signal DQS. Thus, the data DTA may be aligned with the toggle time point of the data strobe signal DQS and may be transmitted to the storage controller 50.

In a data input operation of the nonvolatile memory device 100, when the data signal DQ including the data DTA is received from the storage controller 50, the interface circuit 105 may receive the data strobe signal DQS, which toggles, along with the data DTA from the storage controller 50. The interface circuit 105 may obtain the data DTA from the data signal DQ based on toggle time points of the data strobe signal DQS. For example, the interface circuit 105 may sample the data signal DQ at rising and falling edges of the data strobe signal DQS and may obtain the data DTA.

The interface circuit 105 may transmit a ready/busy signal (e.g., a status signal) nR/B to the storage controller 50 through the eighth pin P18. The interface circuit 105 may transmit state information of the nonvolatile memory device 100 through the ready/busy signal nR/B to the storage controller 50. When the nonvolatile memory device 100 is in a busy state (e.g., when operations are being performed in the nonvolatile memory device 100), the interface circuit 105 may transmit the ready/busy signal nR/B indicating the busy state to the storage controller 50. When the nonvolatile memory device 100 is in a ready state (e.g., when operations are not performed or are completed in the nonvolatile memory device 100), the interface circuit 105 may transmit the ready/busy signal nR/B indicating the ready state to the storage controller 50.

The control circuit 450 may control overall operations of the nonvolatile memory device 100. The control circuit 450 may receive the command CMD and the address ADDR obtained from the interface circuit 105. The control circuit 450 may generate control signals for controlling other components of the nonvolatile memory device 100 in response to the received command CMD and the received address ADDR. For example, the control circuit 450 may generate various control signals for programming the data DTA to the memory cell array 200 or for reading the data DTA from the memory cell array 200.

The memory cell array 200 may store the data DTA obtained from the interface circuit 105, under the control of the control circuit 450. The memory cell array 200 may output the stored data DTA to the interface circuit 105 under the control of the control circuit 480.

The memory cell array 200 may include a plurality of nonvolatile memory cells.

The storage controller 50 may include first to eighth pins P21, P22, P23, P24, P25, P26, P27 and P28 and an interface circuit 99. The interface circuit 99 may be referred to as a second interface circuit or a controller interface circuit. The interface circuit 99 may correspond to the memory interface 98 in FIG. 9. The first to eighth pins P21 to P28 may correspond to the first to eighth pins P11 to P18 of the nonvolatile memory device 100, respectively.

The interface circuit 99 may transmit the chip enable signal nCE to the nonvolatile memory device 100 through the first pin P21. The interface circuit 99 may transmit and receive signals to and from the nonvolatile memory device 100, which is selected by the chip enable signal nCE, through the second to eighth pins P22 to P28.

The interface circuit 99 may transmit the command latch enable signal CLE, the address latch enable signal ALE and the write enable signal nWE to the nonvolatile memory device 100 through the second to fourth pins P22 to P24. The interface circuit 99 may transmit or receive the data signal DQ to and from the nonvolatile memory device 100 through the seventh pin P27.

The interface circuit 99 may transmit the data signal DQ including the command CMD or the address ADDR to the nonvolatile memory device 100 along with the write enable signal nWE, which toggles. The interface circuit 99 may transmit the data signal DQ including the command CMD to the nonvolatile memory device 100 by transmitting the command latch enable signal CLE having an enable state. Also, the interface circuit 99 may transmit the data signal DQ including the address ADDR to the nonvolatile memory device 100 by transmitting the address latch enable signal ALE having an enable state.

The interface circuit 99 may transmit the read enable signal nRE to the nonvolatile memory device 100 through the fifth pin P25. The interface circuit 99 may receive or transmit the data strobe signal DQS from or to the nonvolatile memory device 100 through the sixth pin P26.

The interface circuit 99 may receive the ready/busy signal nR/B from the nonvolatile memory device 100 through the eighth pin P28. The interface circuit 99 may determine state information of the nonvolatile memory device 100 based on the ready/busy signal nR/B.

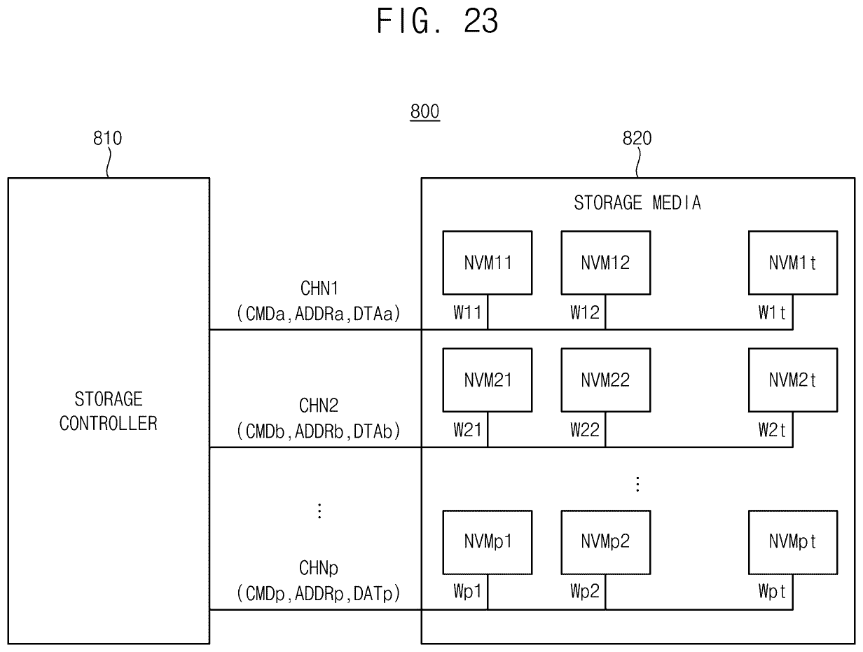

FIG. 23 is a block diagram illustrating a storage device according to example embodiments.

Referring to FIG. 23, a storage device 800 may include a storage controller 810 and a storage media 820. The storage device 800 may support a plurality of media channels CHN1, CHN2, . . . , CHNp (hereinafter CHN1 to CHNp), and the storage media 820 may be connected to the storage controller 810 through the plurality of media channels CHN1 to CHNp.

The storage media 820 may include a plurality of nonvolatile memory devices NVM11, NVM12, . . . , NVM1t, NVM21, NVM22, . . . , NVM2t, NVMp1, NVMp2, . . . , NVMpt. For example, the nonvolatile memory devices NVM11 to NVMpt may correspond to the nonvolatile memory device 100 FIG. 1. Each of the nonvolatile memory devices NVM11 to NVMpt may be connected to one of the plurality of media channels CHN1 to CHNp through a way corresponding thereto. For instance, the nonvolatile memory devices NVM11 to NVM1t may be connected to the first medial channel CHN1 through ways W11, W12, . . . , W1t, the nonvolatile memory devices NVM21 to NVM2t may be connected to the second media channel CHN2 through ways W21, W22, . . . , W2t, and the nonvolatile memory devices NVMp1 to NVMpt may be connected to the p-th media channel CHNp through ways Wp1, Wp2, . . . , Wpt. In some example embodiments, each of the nonvolatile memory devices NVM11 to NVMpt may be implemented as an arbitrary memory unit that may operate according to an individual command from the storage controller 810. For example, each of the nonvolatile memory devices NVM11 to NVMpt may be implemented as a chip or a die, but example embodiments are not limited thereto.

Each of the nonvolatile memory devices NVM11 to NVMpt may correspond to the nonvolatile memory device 100 FIG. 10. Therefore, each of the nonvolatile memory devices NVM11 to NVMpt may include a memory cell array including at least one memory block and the at least one memory block may be divided into a plurality of sub-blocks. Therefore, the storage controller 810 may designate at least one word-line sensitive to read disturbance as additional target word-lines, among word-lines of the unselected sub-block in addition to target word-lines sensitive to read disturbance, among word-lines of the selected sub-block, may perform the reliability verification operation on the target word-lines and the additional target word-lines and may perform reclaim operation based on a result of the reliability verification operation. Therefore, the storage controller 810 may enhance reliability and performance.

The storage controller 810 may transmit and receive signals to and from the storage media 820 through the plurality of media channels CHN1 to CHNp. For example, the storage controller 810 may correspond to the memory controller 50 in FIG. 9. For example, the storage controller 810 may transmit commands CMDa, CMDb, . . . , CMDp, addresses ADDRa, ADDRb, . . . , ADDRp and data DTAa, DTAb, . . . , DTAp to the storage media 820 through the media channels CHN1 to CHNp or may receive the DTAa to DTAp from the storage media 820.

The storage controller 810 may select one of the nonvolatile memories NVM11 to NVMpt, which is connected to each of the media channels CHN1 to CHNp, by using a corresponding one of the media channels CHN1 to CHNp, and may transmit and receive signals to and from the selected nonvolatile memory device.

The storage controller 810 may transmit and receive signals to and from the storage media 820 in parallel through different media channels.

The storage controller 810 may communicate with an external host through universal flash storage (UFS) standard.

A nonvolatile memory device or a storage device according to example embodiments may be packaged using various package types or package configurations.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. A storage device comprising:
a nonvolatile memory device that includes at least one memory block including a plurality of cell strings where each of the plurality of cell strings includes a string selection transistor, a plurality of memory cells and a ground selection transistor which are connected in series and disposed in one direction between a bit-line and a common source line, the at least one memory block being divided into a plurality of sub-blocks disposed in the one direction; and
a storage controller including a reclaim register, wherein the storage controller is configured to:
identify the plurality of sub-blocks as a selected sub-block including a selected word-line and at least one unselected sub-block adjacent to the selected sub-block, based on an access address;
adaptively determine K target word-lines of the selected sub-block and the at least one unselected sub-block based on a program progress state of each of the selected sub-block and the at least one unselected sub-block, K being an integer greater than two; and
perform a reliability verification operation on the K target word-lines sequentially.

2. The storage device of claim 1,
wherein the reliability verification operation indicates an operation of reading data from memory cells connected with at least one word-line among the K target word-lines, and detecting and correcting an error of the read data,
wherein the program progress state of each of the selected sub-block and the at least one unselected sub-block includes an open state, a closed state and an erased state, the open state indicates that each of the selected sub-block and the at least one unselected sub-block includes at least one erased word-line, the closed state indicates that each of the selected sub-block and the at least one unselected sub-block includes only programmed word-lines, and the erased state indicates that each of the selected sub-block and the at least one unselected sub-block includes only erased word-lines, and
wherein the selected sub-block includes the selected word-line designated by the access address.

3. The storage device of claim 2, wherein, based on the selected sub-block being in the closed state and the unselected sub-block being in the closed state,
the storage controller is configured to determine (i) an adjacent word-line adjacent to the selected word-line among first word-lines of the selected sub-block, (ii) a first sub-target word-line adjacent to the unselected sub-block among the first word-lines, and (iii) a second sub-target word-line adjacent to the selected sub-block among second word-lines of the unselected sub-block, as the K target word-lines.

4. The storage device of claim 3, wherein, based on an error count obtained through the reliability verification operation on the adjacent word-line being greater than a reference error count, the storage controller is configured to:
register the selected sub-block in the reclaim register as a reclaimed sub-block;
skip the reliability verification operation on the first sub-target word-line; and
perform the reliability verification operation on the second sub-target word-line.

5. The storage device of claim 2, wherein, based on the selected sub-block being in the closed state and the unelected sub-block being in the erased state, or based on the selected sub-block being in the closed state and the unselected sub-block being in the open state,
the storage controller is configured to determine (i) an adjacent word-line adjacent to the selected word-line among first word-lines of the selected sub-block, (ii) a first sub-target word-line adjacent to the unselected sub-block among the first word-lines, (iii) a boundary word-line adjacent to at least one programmed word-line among second word-lines of the unselected sub-block, and (iv) a second sub-target word-line adjacent to the selected sub-block among the second word-lines, as the K target word-lines.

6. The storage device of claim 5, wherein, based on an error count obtained through the reliability verification operation on the boundary word-line being greater than a reference error count, the storage controller is configured to:
register the unselected sub-block in the reclaim register as a reclaimed sub-block; and
skip the reliability verification operation on the second sub-target word-line.

7. The storage device of claim 2, wherein, based on the selected sub-block being in the open state and the unselected sub-block being in the closed state,
the storage controller is configured to determine (i) a boundary word-line adjacent to at least one programmed word-line among first word-lines of the selected sub-block (ii) an adjacent word-line adjacent to the selected word-line among first word-lines of the selected sub-block, (iii) a first sub-target word-line adjacent to the unselected sub-block among the first word-lines, and (iv) a second sub-target word-line adjacent to the selected sub-block among second word-lines of the unselected sub-block, as the K target word-lines.

8. The storage device of claim 7, wherein, based on an error count obtained through the reliability verification operation on the boundary word-line being greater than a reference error count, the storage controller is configured to:
register the selected sub-block in the reclaim register as a reclaimed sub-block;
skip the reliability verification operation on the adjacent word-line and the first sub-target word-line; and
perform the reliability verification operation on the second sub-target word-line.

9. The storage device of claim 2, wherein, based on the selected sub-block being in the open state and the unelected sub-block being in the erased state or based on the selected sub-block being in the open state and the unselected sub-block being in the open state,
the storage controller is configured to determine (i) a first boundary word-line adjacent to at least one first programmed word-line among first word-lines of the selected sub-block, (ii) an adjacent word-line adjacent to the selected word-line among first word-lines of the selected sub-block, (iii) a first sub-target word-line adjacent to the unselected sub-block among the first word-lines, (iv) a second boundary word-line adjacent to at least one second programmed word-line among second word-lines of the unselected sub-block, and (v) a second sub-target word-line adjacent to the selected sub-block among the second word-lines, as the K target word-lines.

10. The storage device of claim 9, wherein, based on an error count obtained through the reliability verification operation on the first boundary word-line being greater than a reference error count, the storage controller is configured to:
register the selected sub-block in the reclaim register as a reclaimed sub-block;
skip the reliability verification operation on the adjacent word-line and the first sub-target word-line; and
perform the reliability verification operation on the second boundary word-line and the second sub-target word-line.

11. The storage device of claim 1, wherein the storage controller includes:
a reliability manager configured to perform the reliability verification operation based on read disturbance level monitoring scheme;
an error correction code (ECC) engine configured to detect and correct an error of a read data read by the reliability manager by performing an ECC decoding on the read data;
a memory interface configured to communicate with the nonvolatile memory device; and
a processor configured to control the reliability manager, the ECC engine and the memory interface,
wherein, based on an error count in the read data being greater than a reference error count, the processor is configured to register a corresponding sub-block in the reclaim register as a reclaimed sub-block or perform a reclaim operation on the corresponding sub-block.

12. The storage device of claim 1, further comprising:
a voltage generator configured to generate a read voltage and a read pass voltage and the erase voltage based on a control signal;
an address decoder configured to provide the read voltage and the read pass voltage to the selected sub-block and the unselected sub-block based on the access address; and
a control circuit configured to perform the reliability verification by controlling the voltage generator and the address decoder under control of the storage controller.

13. A method of operating a storage controller configured to control a nonvolatile memory device that includes at least one memory block including a plurality of cell strings where each of the plurality of cell strings includes a string selection transistor, a plurality of memory cells and a ground selection transistor which are connected in series and disposed in one direction between a bit-line and a common source line, the at least one memory block being divided into a plurality of sub-blocks disposed in the one direction, the method comprising:
identifying the plurality of sub-blocks as a selected sub-block including a selected word-line and at least one unselected sub-block adjacent to the selected sub-block, based on an access address;
adaptively determining K target word-lines of the selected sub-block and the at least one unselected sub-block based on a program progress state of each of the selected sub-block and the at least one unselected sub-block, K being an integer greater than two; and
performing a reliability verification operation on the K target word-lines sequentially.

14. The method of claim 13,
wherein the reliability verification operation indicates an operation of reading data from memory cells connected with at least one word-line among the K target word-lines, and detecting and correcting an error of the read data,
wherein the program progress state of each of the selected sub-block and the at least one unselected sub-block includes an open state, a closed state, and an erased state, the open state indicates that each of the selected sub-block and the at least one unselected sub-block includes at least one erased word-line, the closed state indicates that each of the selected sub-block and the at least one unselected sub-block includes only programmed word-lines, and the erased state indicates that each of the selected sub-block and the at least one unselected sub-block includes only erased word-lines, and
wherein the selected sub-block includes the selected word-line designated by the access address.

15. The method of claim 14, wherein, based on the selected sub-block being in the closed state and the unelected sub-block being in the closed state,
the K target word-lines include (i) an adjacent word-line adjacent to the selected word-line among first word-lines of the selected sub-block, (ii) a first sub-target word-line adjacent to the unselected sub-block among the first word-lines, and (iii) a second sub-target word-line adjacent to the selected sub-block among second word-lines of the unselected sub-block.

16. The method of claim 15, wherein, based on an error count obtained through the reliability verification operation on the adjacent word-line being greater than a reference error count, the performing the reliability verification operation sequentially includes:
registering the selected sub-block in a reclaim register in the storage controller as a reclaimed sub-block;
skipping the reliability verification operation on the first sub-target word-line; and
performing the reliability verification operation on the second sub-target word-line.

17. The method of claim 14, wherein, based on the selected sub-block being in the closed state and the unelected sub-block being in the erased state, or based on the selected sub-block being in the closed state and the unselected sub-block being in the open state,
the K target word-lines include (i) an adjacent word-line adjacent to the selected word-line among first word-lines of the selected sub-block, (ii) a first sub-target word-line adjacent to the unselected sub-block among the first word-lines, (iii) a boundary word-line adjacent to at least one programmed word-line among second word-lines of the unselected sub-block, and (iv) a second sub-target word-line adjacent to the selected sub-block among the second word-lines.

18. The method of claim 14, wherein, based on the selected sub-block being in the open state and the unselected sub-block being in the closed state,
the K target word-lines include (i) a boundary word-line adjacent to at least one programmed word-line among first word-lines of the selected sub-block (ii) an adjacent word-line adjacent to the selected word-line among first word-lines of the selected sub-block, (iii) a first sub-target word-line adjacent to the unselected sub-block among the first word-lines, and (iv) a second sub-target word-line adjacent to the selected sub-block among second word-lines of the unselected sub-block.

19. The method of claim 14, wherein, based on the selected sub-block being in the open state and the unelected sub-block being in the erased state, or based on the selected sub-block being in the open state and the unselected sub-block being in the open state,
the K target word-lines include (i) a first boundary word-line adjacent to at least one first programmed word-line among first word-lines of the selected sub-block, (ii) an adjacent word-line adjacent to the selected word-line among first word-lines of the selected sub-block, (iii) a first sub-target word-line adjacent to the unselected sub-block among the first word-lines, (iv) a second boundary word-line adjacent to at least one second programmed word-line among second word-lines of the unselected sub-block, and (v) a second sub-target word-line adjacent to the selected sub-block among second word-lines of the unselected sub-block.

20. A storage device comprising:
a nonvolatile memory device that includes at least one memory block including a plurality of memory cells, the at least one memory block including a plurality of sub-blocks; and
a storage controller configured to:
identify the plurality of sub-blocks as a selected sub-block including a selected word-line and at least one unselected sub-block adjacent to the selected sub-block, based on an access address;
adaptively determine K target word-lines of the selected sub-block and the at least one unselected sub-block based on a program progress state of each of the selected sub-block and the at least one unselected sub-block, K being an integer greater than two; and
perform a reliability verification operation on the K target word-lines sequentially, and
wherein the storage controller include:
a reclaim register;
a reliability manager configured to perform the reliability verification operation based on read disturbance level monitoring scheme;
an error correction code (ECC) engine configured to detect and correct an error of a read data read by the reliability manager by performing an ECC decoding on the read data; and
a processor configured to control the reliability manager and the ECC engine,
wherein, based on an error count in the read data being greater than a reference error count, the processor is configured to register a corresponding sub-block in the reclaim register as a reclaimed sub-block.
